(19) United States
(12) Patent Application Publication
(10) Pub. No.: US 2026/0101829 A1
(43) Pub. Date: Apr. 9, 2026

(54) PACKAGED MODULE HAVING THIN SUBSTRATE

(71) Applicant: SKYWORKS SOLUTIONS, INC., Irvine, CA (US)

(72) Inventors: Reza KASNAVI, Solana Beach, CA (US); Howard E. CHEN, Anaheim, CA (US); Ki Wook LEE, Irvine, CA (US); Jeffrey SAILER, Cedar Rapids, IA (US); Sundeep Nand NANGALIA, Raleigh, NC (US); Behnam ANALUI, Irvine, CA (US)

(21) Appl. No.: 19/346,243

(22) Filed: Sep. 30, 2025

Related U.S. Application Data
(60) Provisional application No. 63/700,970, filed on Sep. 30, 2024.

(51) Int. Cl. H10W 90/22; H03H 9/54; H10W 42/20; H10W 70/09; H10W 74/01; H10W 74/10; H10W 90/00

(52) U.S. Cl. CPC H10W 90/22; H03H 9/54; H10W 42/20; H10W 70/09; H10W 74/016; H10W 74/019; H10W 74/117; H10W 74/141; H10W 90/7295

(57) ABSTRACT

A packaged module can include a packaging substrate having first and second side with a plurality of layers therebetween in a printed circuit board configuration and having a thickness that is less than 200 μm, and a first-side portion including a first component mounted on the first side of the packaging substrate and a first mold structure implemented to at least partially encapsulate the first component. The packaged module can further include a second-side portion including a second component mounted on the second side of the packaging substrate and a plurality of conductive mounting structures. The second-side portion can further include a second mold structure implemented to at least partially encapsulate the second component, with the second mold structure further encapsulating the conductive mounting features while providing respective exposed mounting surfaces of the conductive mounting features.

### CROSS-REFERENCE T0 RELATED APPLICATION(S)

This application claims priority to U.S. Provisional Application No. 63/700,970 filed Sep. 30, 2024, entitled PACKAGED MODULE HAVING THIN SUBSTRATE, the disclosure of which is hereby expressly incorporated by reference herein in its entirety.

### BACKGROUND

### Field

The present disclosure relates to packaged electronic modules such as packaged modules for radio-frequency applications.

### Description of the Related Art

In many electronics applications, radio-frequency (RF) circuits and/or circuit elements are implemented as parts of packaged modules. A packaged module typically includes a packaging substrate configured to receive and support a plurality of components such as semiconductor die and/or circuit elements such as discrete passive components. In some applications, such a packaged module can include one or more of the foregoing devices mounted on one side of the packaging substrate, and the other side can be provided with mounting structures such as a ball grid array.

### SUMMARY

In accordance with a number of implementations, the present disclosure relates to a packaged module that includes a packaging substrate having first and second side with a plurality of layers therebetween in a printed circuit board configuration, and having a thickness that is less than 200 μm. The packaged module further includes a first-side portion implemented on the first side of the packaging substrate and including a first component mounted on the first side of the packaging substrate, with the first-side portion further including a first mold structure implemented to at least partially encapsulate the first component. The packaged module further includes a second-side portion implemented on the second side of the packaging substrate and including a second component mounted on the second side of the packaging substrate, and a plurality of conductive mounting structures, with the second-side portion further including a second mold structure implemented to at least partially encapsulate the second component, and the second mold structure further encapsulating the conductive mounting features while providing respective exposed mounting surfaces of the conductive mounting features.

In some embodiments, the thickness of the packaging substrate can be less than 150 μm, 100 μm, 90 μm, 80 μm, 70 μm, 60 μm, or 50 μm. In some embodiments, the packaging substrate can include a first outermost layer that defines the first side and a second outermost layer that defines the second side. The first component can be mounted directly on the first side, and the second component can be mounted directly on the second side.

In some embodiments, the first component can be implemented as a die, and the second component can be implemented as a die. Each of the first and second die can be configured to provide a radio-frequency functionality. The radio-frequency functionality of each of the first and second die can include a filtering functionality. Each of the first and second die can be configured as an acoustic filter device. The first acoustic filter device can be a multilayer piezoelectric substrate (MPS) filter or a bulk acoustic wave (BAW) filter, and the second acoustic filter device can be an MPS filter or a BAW filter.

In some embodiments, the conductive mounting structures of the second-side portion can be implemented as ball-shaped structures or as metal posts.

In some embodiments, first mold structure can be implemented to fully encapsulate non-mounting surface and side walls of the first component.

In some embodiments, the first mold structure can be implemented to expose a non-mounting surface of the first component. The exposed non-mounting surface of the first component can result from a thinning operation that removes a portion of the first component. The exposed non-mounting surface of the first component can include a ground surface that provides a desired thickness of the first-side portion.

In some embodiments, the second mold structure can be implemented to fully encapsulate non-mounting surface and side walls of the second component.

In some embodiments, the second mold structure can be implemented to expose a non-mounting surface of the second component. The exposed non-mounting surface of the second component can result from a thinning operation that removes a portion of the second component. The exposed non-mounting surface of the second component can include a ground surface that provides a desired thickness of the second-side portion.

In some embodiments, the packaged module can further include an electromagnetic shielding feature including a conductive shielding layer that substantially covers all sides of the packaged module except a mounting side associated with the exposed mounting surfaces of the conductive mounting features, with the conductive shielding layer being electrically connected to a ground plane within the packaging substrate. The conductive shielding layer can include a conductive layer formed from a conformal deposition process.

In some embodiments, the first component can be mounted on the first side of the packaging substrate to provide a no-gap configuration therebetween. The first component can include a mounting side that is patterned to allow the mounting side to be mated directly with a corresponding patterned area on the first side of the packaging substrate. The second component can be mounted on the second side of the packaging substrate to provide a gap therebetween. The second component can be mounted to the second side of the packaging substrate with a surface mount technology configuration. The second mold structure can also fill the gap between the second component and the second side of the packaging substrate.

In some embodiments, the packaging substrate can include a passive circuit element implemented as one or more features printed on one or more layers of the packaging substrate. The passive circuit element can include an inductor, a capacitor or a resistor.

In some implementations, the present disclosure relates to a method for manufacturing a packaged module. The method includes providing a carrier, forming a first-side portion of a dual-sided module on the carrier, and removing the carrier from the first-side portion to provide a surface. The method further includes providing or forming a packaging substrate on the first-side portion such that the packaging substrate has a thickness less than 200 μm, and such that a first side of the packaging substrate engages the surface of the first-side portion and a second side of the packaging substrate is opposite from the first side. The method further includes forming a second-side portion of the dual-sided module on the second side of the packaging substrate.

In some embodiments, the thickness of the packaging substrate can be less than 150 μm, 100 μm, 90 μm, 80 μm, 70 μm, 60 μm, or 50 μm.

In some embodiments, the forming of the first-side portion can include attaching a first component on a surface of the carrier, and forming a first mold structure over the surface of the carrier to at least partially encapsulate the first component.

In some embodiments, the removing of the carrier from the first-side portion can include a debonding process.

In some embodiments, the packaging substrate can be a pre-fabricated packaging substrate having multiple layers such that a first outermost layer defines the first side and a second outermost layer defines the second side. The first side of the packaging substrate can directly engage the surface of the first-side portion. The first side of the packaging substrate can engage a mounting surface of the first component to provide a gapless interconnect between the first component and the first side of the packaging substrate.

In some embodiments, the packaging substrate can be formed over the surface of the first-side portion. The forming of the packaging substrate can include forming multiple layers such that a first outermost layer defines the first side and a second outermost layer defines the second side. The first side of the packaging substrate can directly engage the surface of the first-side portion. The first side of the packaging substrate can engage a mounting surface of the first component to provide a gapless interconnect between the first component and the first side of the packaging substrate.

In some embodiments, the forming of the second-side portion can include mounting a second component on the second side of the packaging substrate, implementing a plurality of conductive mounting features on the second side of the packaging substrate, and forming a second mold structure to at least partially encapsulate the second component and the conductive mounting features while providing respective exposed mounting surfaces of the conductive mounting features. The mounting of the second component can be performed before the implementing of the plurality of conductive mounting features. The mounting of the second component can be performed after the implementing of the plurality of conductive mounting features.

The forming of the second mold structure can include forming a mold structure that fully covers the second component and the conductive mounting features, and performing a thinning operation to expose the mounting surfaces of the conductive mounting features. The thinning operation can be performed to expose a non-mounting surface of the second component. The thinning operation can remove a portion of the second component. The thinning operation can include a grinding operation that provides a ground surface as the exposed non-mounting surface of the second component, to thereby provide a desired thickness of the second-side portion.

In some embodiments, the forming of the first mold structure can include forming a mold structure that fully covers the first component, and performing a thinning operation to reduce the thickness of the first mold structure. The thinning operation can be performed to expose a non-mounting surface of the first component. The thinning operation can remove a portion of the first component. The thinning operation can include a grinding operation that provides a ground surface as the exposed non-mounting surface of the first component, to thereby provide a desired thickness of the first-side portion.

In some embodiments, the carrier can include a metal carrier.

In some embodiments, the carrier can be dimensioned to allow processing of an array of units with each including a respective first-side portion, a respective packaging substrate, and a respective second-side portion, such that an array of packaged modules are manufactured while in an array format. The method can further include singulating the array of packaged modules into a plurality of individual packaged modules.

In some implementations, the present disclosure relates to a method for manufacturing packaged modules. The method includes providing a carrier, and providing or forming a packaging substrate on the carrier, such that the packaging substrate has a thickness less than 200 μm, and such that the packaging substrate includes first and second sides with the second side engaging the carrier. The method further includes forming a first-side portion of a dual-sided module on the first side of the packaging substrate, removing the carrier from the second side of the packaging substrate, and forming a second-side portion of the dual-sided module on the second side of the packaging substrate.

In some embodiments, the thickness of the packaging substrate can be less than 150 μm, 100 μm, 90 μm, 80 μm, 70 μm, 60 μm, or 50 μm.

In some embodiments, the forming of the first-side portion can include attaching a first component on the first side of the packaging substrate, and forming a first mold structure over the first side of the packaging substrate to at least partially encapsulate the first component.

In some embodiments, the removing of the carrier from the packaging substrate can include a debonding process.

In some embodiments, the packaging substrate can be a pre-fabricated packaging substrate having multiple layers such that a first outermost layer defines the first side and a second outermost layer defines the second side. The first side of the packaging substrate can engage a mounting surface of the first component to provide a gapless interconnect between the first component and the first side of the packaging substrate. The second side of the packaging substrate can directly engage the carrier.

In some embodiments, the packaging substrate can be formed over the carrier. The forming of the packaging substrate can include forming multiple layers such that a first outermost layer defines the first side and a second outermost layer defines the second side. The first side of the packaging substrate can engage a mounting surface of the first component to provide a gapless interconnect between the first component and the first side of the packaging substrate. The second side of the packaging substrate can directly engage the carrier.

In some embodiments, the forming of the second-side portion can include mounting a second component on the second side of the packaging substrate, implementing a plurality of conductive mounting features on the second side of the packaging substrate, and forming a second mold structure to at least partially encapsulate the second component and the conductive mounting features while providing respective exposed mounting surfaces of the conductive mounting features. The mounting of the second component can be performed before the implementing of the plurality of conductive mounting features. The mounting of the second component can be performed after the implementing of the plurality of conductive mounting features. The forming of the second mold structure can include forming a mold structure that fully covers the second component and the conductive mounting features, and performing a thinning operation to expose the mounting surfaces of the conductive mounting features. The thinning operation can be performed to expose non-mounting surface of the second component. The thinning operation can remove a portion of the second component. The thinning operation can include a grinding operation that provides a ground surface as the exposed non-mounting surface of the second component, to thereby provide a desired thickness of the second-side portion.

In some embodiments, the forming of the first mold structure can include forming a mold structure the fully covers the first component, and performing a thinning operation to reduce the thickness of the first mold structure. The thinning operation can be performed to expose a non-mounting surface of the first component. The thinning operation can remove a portion of the first component. The thinning operation can include a grinding operation that provides a ground surface as the exposed non-mounting surface of the first component, to thereby provide a desired thickness of the first-side portion.

In some embodiments, the carrier can include a metal carrier.

In some embodiments, the carrier can be dimensioned to allow processing of an array of units each including a respective first-side portion, a respective packaging substrate, and a respective second-side portion, such that an array of packaged modules are manufactured while in an array format. The method can further include singulating the array of packaged modules into a plurality of individual packaged modules.

In some implementations, the present disclosure relates to a packaged module that includes a packaging substrate having first and second sides with a plurality of layers therebetween in a printed circuit board configuration, and having a thickness that is less than 200 μm. The packaged module further includes a filter die implemented on the first side of the packaging substrate, and a plurality of pins implemented on the second side of the packaging substrate, such that the packaging substrate include a fan out circuit between the filter die and the pins. The packaged module further includes a passive element implemented as part of the packaging substrate and configured to support operation of the filter die.

In some embodiments, the thickness of the packaging substrate can be less than 150 μm, 100 μm, 90 μm, 80 μm, 70 μm, 60 μm, or 50 μm.

In some embodiments, the packaged module can further include a mold structure implemented on the first side of the packaging substrate to at least partially encapsulate the filter die. The mold structure can be configured to completely encapsulate the filter die. The mold structure can be configured to expose a back side the filter die. The mold structure can include a surface that exposes the back side the filter die, the surface of the mold structure being formed from a thinning operation. The exposed back side the filter die can be formed from removal of at least some material from the back side of the filter die. The exposed back side the filter die and the surface of the mold structure can be substantially co-planar.

In some embodiments, the mold structure can be formed from a low pressure liquid molding process.

In some embodiments, the plurality of layers of the packaging substrate can include a first outermost layer that defines the first side and a second outermost layer that defines the second side. The filter die can be implemented directly on the first side, and the pins can be implemented directly on the second side.

In some embodiments, the pins can be implemented as ball-shaped structures such as solder balls. The pins can be implemented as metal posts such as copper posts.

In some embodiments, the filter die can be mounted on the first side of the packaging substrate to provide a no-gap configuration therebetween. The filter die can include a mounting side that is patterned to allow the mounting side to be mated directly with a corresponding patterned area on the first side of the packaging substrate.

In some embodiments, the passive element can be implemented as one or more features printed on one or more layers of the packaging substrate.

In some embodiments, the passive element can include an inductor, a capacitor or a resistor. The passive element can be configured to provide a radio-frequency functionality with respect to the filter die. The radio-frequency functionality can include a matching functionality. The passive element can be configured to provide the radio-frequency functionality with a desired quality factor.

In some embodiments, the passive element can be implemented on a selected layer of the packaging substrate. The selected layer can include a layer at or closest to the first side of the packaging substrate. The selected layer can include a layer adjacent to a layer associated with the first side of the substrate.

In some embodiments, the packaged module can further include another passive element implemented as part of the packaging substrate and configured to support operation of the filter die. The passive element and the other passive element can be implemented on a common layer or on different layers.

In some embodiments, the passive element can be implemented to provide a lateral footprint that at least partially overlaps with a lateral footprint of the filter die to allow reduction of lateral dimensions of the packaged module.

In some embodiments, the filter die can be implemented as an acoustic wave filter die such as a surface acoustic wave (SAW) filter, a bulk acoustic wave (BAW) filter, or a multilayer piezoelectric substrate (MPS) filter.

In some embodiments, the packaged module can further include another filter die implemented on the first side of the packaging substrate. Each of the filter die and the other filter die can be implemented as an acoustic wave filter die. The acoustic wave filter die and the other acoustic wave filter die can be implemented as same type of acoustic wave filter device, or as different types of acoustic wave filter devices.

In some implementations, the present disclosure related to a method for manufacturing a packaged module. The method includes providing a carrier, forming a first-side portion of a module on the carrier, and removing the carrier from the first-side portion to provide a surface. The method further includes providing or forming a packaging substrate on the first-side portion such that the packaging substrate has a thickness less than 200 μm, and such that the packaging substrate includes a passive element, and such that a first side of the packaging substrate engages the surface of the first-side portion and a second side of the packaging substrate is opposite from the first side. The method further includes forming a second-side portion of the module on the second side of the packaging substrate.

In some embodiments, the forming of the first-side portion can include attaching a filter die on a surface of the carrier, and forming a mold structure over the surface of the carrier to at least partially encapsulate the filter die. The forming of the mold structure can result in the mold structure fully encapsulating the filter die. The forming of the mold structure can result in the mold structure exposing a back side the filter die. The forming of the mold structure can include a mold forming process that results in the mold structure fully encapsulating the filter die, and a thinning process that results in the mold structure being thinned to expose the back side of the filter die. The thinning process can include a grinding process. The thinning process can result in the exposed back side of the filter die being formed from removal of at least some material from the back side of the filter die. The thinning process can result in the exposed back side of the filter die and the surface of the mold structure being substantially co-planar.

In some embodiments, the removing of the carrier from the first-side portion can include a debonding process.

In some embodiments, the packaging substrate can be a pre-fabricated substrate having multiple layers such that a first outermost layer defines the first side and a second outermost layer defines the second side. The first side of the packaging substrate can directly engage the surface of the first-side portion. The first side of the packaging substrate can engage a mounting surface of a filter die of the first-side portion to provide a gapless interconnect between the filter die and the first side of the packaging substrate.

In some embodiments, the packaging substrate can be formed over the surface of the first-side portion. The forming of the packaging substrate can include forming multiple layers such that a first outermost layer defines the first side and a second outermost layer defines the second side. The first side of the packaging substrate can directly engage the surface of the first-side portion including a filter die. The first side of the packaging substrate can engage a mounting surface of the filter die to provide a gapless interconnect between the filter die and the first side of the packaging substrate.

In some embodiments, the forming of the second-side portion can include implementing a plurality of pins on the second side of the packaging substrate.

In some embodiments, the carrier can include a metal carrier.

In some embodiments, the carrier can be dimensioned to allow processing of an array of units each including a respective first-side portion, such that an array of packaged modules are manufactured while in an array format. The method can further include singulating the array of packaged modules into a plurality of individual packaged modules.

In some embodiments, the forming or providing of the packaging substrate can include the passive element being implemented as one or more features printed on one or more layers of the packaging substrate.

In some embodiments, the passive element can include an inductor, a capacitor or a resistor. The passive element can be configured to provide a radio-frequency functionality with respect to a filter die of the first-side portion. The radio-frequency functionality can include a matching functionality. The passive element can be configured to provide the radio-frequency functionality with a desired quality factor.

In some embodiments, the passive element can be implemented on a selected layer of the packaging substrate. The selected layer can include a layer at or closest to the first side of the packaging substrate. The selected layer can include a layer adjacent to a layer associated with the first side of the packaging substrate.

In some embodiments, the providing or forming of the packaging substrate can further include implementing another passive element as part of the packaging substrate. The passive element and the other passive element can be implemented on a common layer or on different layers.

In some embodiments, the passive element can be implemented to provide a lateral footprint that at least partially overlaps with a lateral footprint of a filter die of the first-side portion to allow reduction of lateral dimensions of the packaged module.

In some embodiments, the first-side portion can include an acoustic wave filter die such as a surface acoustic wave (SAW) filter, a bulk acoustic wave (BAW) filter, or a multilayer piezoelectric substrate (MPS) filter. The first-side portion can further include another acoustic wave filter die. The acoustic wave filter die and the other acoustic wave filter die can be implemented as same type of acoustic wave filter device or as different types of acoustic wave filter devices.

In some implementations, the present disclosure relates to a method for manufacturing packaged modules. The method includes providing a carrier, and providing or forming a packaging substrate having first and second sides on the carrier such that the packaging substrate has a thickness less than 200 μm, and such that the packaging substrate include a passive element, and such that the second side engages the carrier. The method further includes forming a first-side portion of a module on the first side of the packaging substrate, removing the carrier from the second side of the packaging substrate, and forming a second-side portion of the module on the second side of the packaging substrate.

In some embodiments, the forming of the first-side portion can include attaching a filter die on the first side of the packaging substrate, and forming a mold structure over the first side of the packaging substrate to at least partially encapsulate the filter die.

In some embodiments, the removing of the carrier from the second side of the packaging substrate can include a debonding process.

In some embodiments, the packaging substrate can be a pre-fabricated packaging substrate having multiple layers such that a first outermost layer defines the first side and a second outermost layer defines the second side. The first side of the packaging substrate can directly engage the surface of the first-side portion. The first side of the packaging substrate can engage a mounting surface of a filter die of the first-side portion to provide a gapless interconnect between the filter die and the first side of the packaging substrate.

In some embodiments, the packaging substrate can be formed over the surface of the carrier. The forming of the packaging substrate can include forming multiple layers such that a first outermost layer defines the first side and a second outermost layer defines the second side. The first side of the packaging substrate can directly engage the surface of the first-side portion including a filter die. The first side of the packaging substrate can engage a mounting surface of the filter die to provide a gapless interconnect between the filter die and the first side of the packaging substrate.

In some embodiments, the forming of the second-side portion can include implementing a plurality of pins on the second side of the packaging substrate.

In some embodiments, the carrier can include a metal carrier.

In some embodiments, the carrier can be dimensioned to allow processing of an array of units each including a respective packaging substrate and a respective first-side portion, such that an array of packaged modules are manufactured while in an array format. The method can further include singulating the array of packaged modules into a plurality of individual packaged modules.

In some embodiments, the forming or providing of the packaging substrate can include the passive element being implemented as one or more features printed on one or more layers of the packaging substrate.

In some embodiments, the passive element can include an inductor, a capacitor or a resistor. The passive element can be configured to provide a radio-frequency functionality with respect to a filter die of the first-side portion. The radio-frequency functionality can include a matching functionality. The passive element can be configured to provide the radio-frequency functionality with a desired quality factor.

In some embodiments, the passive element can be implemented on a selected layer of the packaging substrate. The selected layer can include a layer at or closest to the first side of the packaging substrate. The selected layer can include a layer adjacent to a layer associated with the first side of the packaging substrate.

In some embodiments, the providing or forming of the packaging substrate can further include implementing another passive element as part of the packaging substrate. The passive element and the other passive element can be implemented on a common layer or on different layers.

In some embodiments, the passive element can be implemented to provide a lateral footprint that at least partially overlaps with a lateral footprint of a filter die of the first-side portion to allow reduction of lateral dimensions of the packaged module.

In some embodiments, the first-side portion can include an acoustic wave filter die such as a surface acoustic wave (SAW) filter, a bulk acoustic wave (BAW) filter, or a multilayer piezoelectric substrate (MPS) filter. The first-side portion can further include another acoustic wave filter die. The acoustic wave filter die and the other acoustic wave filter die can be implemented as same type of acoustic wave filter device or as different types of acoustic wave filter devices.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a side view of a thin packaging substrate having an overall thickness and a lateral dimension.

FIG. 2A shows an enlarged sectional view of a portion of an example configuration of the thin packaging substrate of FIG. 1.

FIG. 2B shows an enlarged sectional view of a portion of another example configuration of the thin packaging substrate of FIG. 1.

FIG. 2C shows an enlarged sectional view of a portion of yet another example configuration of the thin packaging substrate of FIG. 1.

FIG. 3 shows a side view of an example packaged module that includes a thin packaging substrate such as the thin packaging substrate of FIGS. 1 and 2.

FIGS. 4A to 4E show examples of dual-sided (DS) modules where each includes a thin substrate with a first side and a second side.

FIGS. 5A to 5J show various stages of a process that can be utilized to fabricate a dual-sided module such as any one of the modules of FIGS. 4A to 4E.

FIG. 6 shows a dual-sided module that includes a configuration where a first mold structure is dimensioned to expose at least a portion of a non-mounting side of a component on a first side of a substrate.

FIGS. 7A to 7C show an example process that can be utilized to fabricate the dual-sided module of FIG. 6.

FIG. 8A show a dual-sided module that is similar to the module of FIG. 5J.

FIG. 8B shows an enlarged view of the packaging substrate of FIG. 8A by itself.

FIGS. 9A to 9E show various stages of a process where a dual-sided module having one or more features as described herein can be fabricated where a thin substrate is provided or constructed on a carrier before building of any side portion of the module.

FIG. 10 shows that in some embodiments, a dual-sided module having one or more features as described herein can include a first component implemented as a first radio-frequency (RF) device, and a second component implemented as a second RF device.

FIG. 11 shows that in some embodiments, the first RF device of FIG. 10 can be a first filter device, and the second RF device of FIG. 10 can be a second filter device.

FIGS. 12A to 12D show non-limiting examples where first and second components of a dual-sided module can be implemented as different combinations of multilayer piezoelectric substrate (MPS) and bulk acoustic wave (BAW) filters.

FIG. 13 shows a dual-sided module having one or more features as described herein, where a first component is coupled to a first side of a packaging substrate, and a second component is coupled to a second side of the packaging substrate.

FIG. 14 shows that in some embodiments, a first interconnect can be configured such that a first component of a dual-sided module is mounted to a first side of a packaging substrate utilizing a surface mount technology (SMT) process.

FIG. 15 shows that in some embodiments, a first interconnect of a dual-sided module can be similar to the example of FIG. 13, and a second interconnect of the dual-sided module can also be implemented to provide a no-gap interconnect configuration.

FIG. 16 shows that in some embodiments, a dual-sided module having one or more features as described herein can include an electromagnetic (EM) shielding feature.

FIG. 17 shows that in some embodiments, a dual-sided module having one or more features as described herein can include a passive circuit element implemented as a part of a packaging substrate.

FIG. 18A shows that in some embodiments, a dual-sided module having one or more features as described herein can include an inductor having inductance L implemented as a part of a packaging substrate.

FIG. 18B shows that in some embodiments, a dual-sided module having one or more features as described herein can include a capacitor having capacitance C implemented as a part of a packaging substrate.

FIG. 18C shows that in some embodiments, a dual-sided module having one or more features as described herein can include a resistor having resistance R implemented as a part of a packaging substrate.

FIG. 19 depicts a packaged module having a packaging substrate as described herein, an RF die implemented on the substrate, and a plurality of pins implemented on the substrate to provide mounting and electrical connection functionalities when mounted on a circuit board.

FIG. 20 shows that in some embodiments, the RF die of FIG. 19 can include acoustic wave device(s).

FIGS. 21A to 21I depict block diagrams of non-limiting examples of packaged modules each having acoustic wave based filter(s), integrated passive element(s) and connection/mounting pins.

FIGS. 22A to 22I depict plan views of the packaged modules of FIGS. 21A to 21I, respectively.

FIG. 23 shows that in some embodiments, a packaged module can include a filtering functionality between an input associated with a pin and an output associated with a pin.

FIG. 24 shows that in some embodiments, a packaged module can include filtering functionalities between a plurality of inputs associated with pins and a plurality of outputs associated with pins.

FIG. 25 shows that in some embodiments, a packaged module can include filtering functionalities between a plurality of nodes associated with pins and a common node associated with a pin.

FIG. 26 shows a side sectional view of a thin packaging substrate that can be utilized to form a packaged module as described herein.

FIGS. 27A to 27G show non-limiting examples of passive elements implemented in packaging substrates of respective packaged modules.

FIG. 28A shows two examples of a passive element implemented as an inductor.

FIG. 28B shows a circuit representation of the inductor of FIG. 28A.

FIG. 29A shows two examples of a passive element implemented as a resistor.

FIG. 29B shows a circuit representation of the resistor of FIG. 29A.

FIG. 30A shows an example of a passive element implemented as a capacitor.

FIG. 30B shows a circuit representation of the capacitor of FIG. 30A.

FIGS. 31A and 31B show that packaged modules having one or more features as described herein can be implemented with different types of mounting/connection pins on a mounting side of a thin packaging substrate.

FIG. 31C shows that in some embodiments, a packaged module having one or more features as described herein can include more than one acoustic wave filter provided on a non-mounting side of a thin packaging substrate.

FIGS. 32A to 32F show various stages of a process that can be utilized to fabricate a packaged module having one or more features as described herein.

FIG. 32G shows the packaged module of FIG. 32F in an inverted orientation relative to the orientation of FIG. 32F.

FIG. 32H shows that in some embodiments, the mold structure of the packaged module of FIG. 32G can be thinned to provide a new thickness dimension.

FIG. 32I shows that in some embodiments, the mold structure of the packaged module of FIG. 32H can be thinned further to provide a new thickness dimension.

FIG. 33 shows a packaged module that is similar to the module of FIG. 31A.

FIGS. 34A to 34F show various stages of a process where a packaged module having one or more features as described herein can be fabricated where a thin packaging substrate is provided or constructed on a carrier before building of any-side portion.

FIGS. 35A to 35C show example stages of fabrication where multiple units are processed while in an array format and then singulated to provide multiple packaged units.

FIGS. 36A to 36C show that in some embodiments, a rectangular shaped carrier can be utilized to fabricate an array of modules having one or more features as described herein.

FIG. 37 shows that in some embodiments, one or more features of the present disclosure can be implemented in a module packaging system.

### DETAILED DESCRIPTION OF SOME EMBODIMENTS

The headings provided herein, if any, are for convenience only and do not necessarily affect the scope or meaning of the claimed invention.

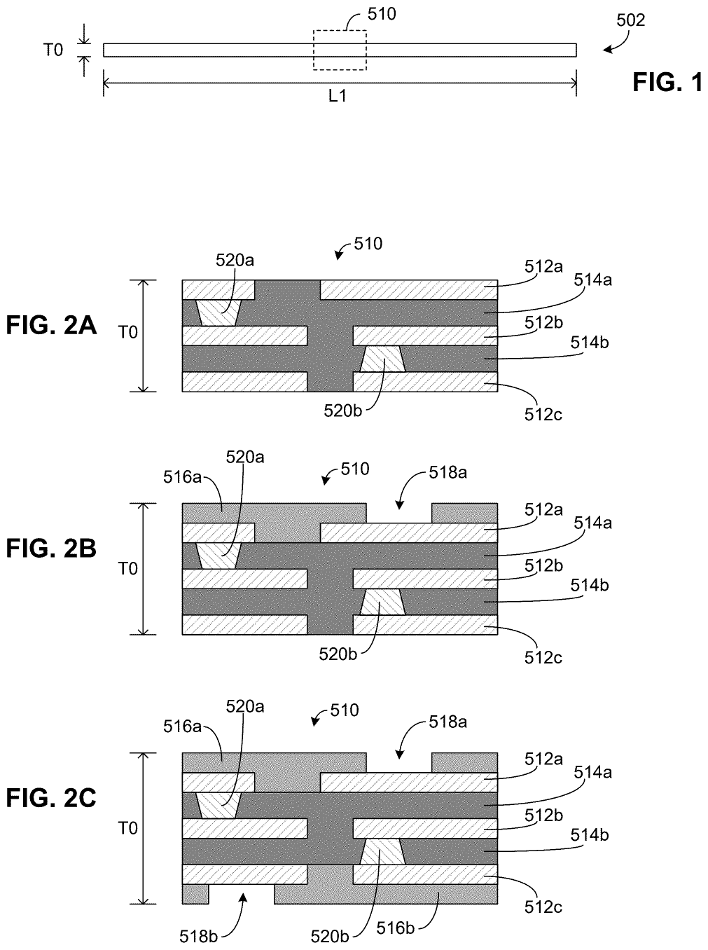

FIG. 1 shows a side view of a thin packaging substrate 502 having an overall thickness of T0 and a lateral dimension of L1. A portion indicated as 510 is shown in an enlarged view in each of FIGS. 2A, 2B, 2C.

In some embodiments, a thin packaging substrate as described herein can be based on printed-circuit-board (PCB) configuration having a plurality of metal layers, implemented so as to have an overall thickness T0 that is less than 200 μm, 150 μm, 100 μm, 90 μm, 80 μm, 70 μm, 60 μm, or 50 μm. For the purpose of description, such a thin packaging substrate may also be referred to herein as an ultra-thin substrate, a thin substrate, a packaging substrate or a substrate.

FIG. 2A shows an enlarged sectional view of a portion 510 of an example configuration of the thin packaging substrate 502 of FIG. 1. In the example of FIG. 2A, the thin packaging substrate is shown to include three layers 512a, 512b, 512c that include, for example, conductive lines and/or pads to provide electrical connectivity for the packaging substrate. As described herein, some or all of such layers can also include one or more passive elements such as inductor(s), capacitor(s) and/or resistor(s).

In the example of FIG. 2A, conductive vias are shown to be provided to electrically connect portions of different layers. For example, a conductive via 520a is shown to electrically connect a portion of the upper layer 512a to a portion of the middle layer 512b; and a conductive via 520b is shown to electrically connect a portion of the middle layer 512b to a portion of the lower layer 512c. It will be understood that a conductive via can also provide electrical connection between further-separated layers.

In the example of FIG. 2A, dielectric material is shown to be provided between two neighboring layers, as well as between conductive features within the same layer. For example, a dielectric layer 514a is shown to be provided between the layers 512a and 512b, and a dielectric layer 514b is shown to be provided between the layers 512b and 512c.

Configured in the foregoing manner, the overall thickness T0 of the thin packaging substrate 502 of FIG. 2A is approximately the sum of the thicknesses of the layers 512a, 512b, 512c and the thicknesses of the dielectric layers 514a, 514b. For example, the thin packaging substrate 502 of FIG. 2A can include 7 μm thick metal (e.g., copper) features in each of the layers 512a, 512b, 512c, and 10 μm thick dielectric for each of the dielectric layers 514a, 514b, thereby providing an overall thickness T0 of approximately 41 μm.

FIG. 2B shows an enlarged sectional view of a portion 510 of another example configuration of the thin packaging substrate 502 of FIG. 1. In the example of FIG. 2B, the thin packaging substrate is shown to include three layers 512a, 512b, 512c and two dielectric layers 514a, 514b, similar to the example of FIG. 2A.

In the example of FIG. 2B, the thin packaging substrate 502 is shown to further include a solder mask layer 516a over the upper layer 512a. Such a solder mask layer can be patterned to, for example, provide an opening 518a to accommodate a conductive mounting pad.

Configured in the foregoing manner, the overall thickness T0 of the thin packaging substrate 502 of FIG. 2B is approximately the sum of the thicknesses of the layers 512a, 512b, 512c, the thicknesses of the dielectric layers 514a, 514b, and the thickness of the solder mask layer 516a. For example, the thin packaging substrate 502 of FIG. 2B can include 7 μm thick metal (e.g., copper) features in each of the layers 512a, 512b, 512c, 10 μm thick dielectric for each of the dielectric layers 514a, 514b, and 8 μm thick solder mask layer 516a, thereby providing an overall thickness T0 of approximately 49 μm.

FIG. 2C shows an enlarged sectional view of a portion 510 of yet another example configuration of the thin packaging substrate 502 of FIG. 1. In the example of FIG. 2C, the thin packaging substrate is shown to include three layers 512a, 512b, 512c and two dielectric layers 514a, 514b, similar to the example of FIG. 2A.

In the example of FIG. 2C, the thin packaging substrate 502 is shown to further include a first solder mask layer 516a over the upper layer 512a, and a second solder mask layer 516b under the lower layer 512c. Such solder mask layers can be patterned to, for example, provide an opening 518a to accommodate a conductive mounting pad for the upper layer 512a and an opening 518b to accommodate a conductive mounting pad for the lower layer 512c.

Configured in the foregoing manner, the overall thickness T0 of the thin packaging substrate 502 of FIG. 2C is approximately the sum of the thicknesses of the layers 512a, 512b, 512c, the thicknesses of the dielectric layers 514a, 514b, and the thicknesses of the solder mask layers 516a, 516b. For example, the thin packaging substrate 502 of FIG. 2C can include 8 μm thick metal (e.g., copper) features in each of the layers 512a, 512b, 512c, 14 μm thick dielectric for each of the dielectric layers 514a, 514b, and 8 μm-thick solder mask layers 516a, 516b, thereby providing an overall thickness T0 of approximately 68 μm. It is noted that a thin packaging substrate similar to the example of FIG. 2C but without the solder mask layers can have an overall thickness of approximately 52 μm.

In the examples of FIGS. 2A to 2C, each thin packaging substrate is depicted as having three layers (512a, 512b, 512c). However, it will be understood that a thin packaging substrate having one or more features as described herein can include different numbers of layers.

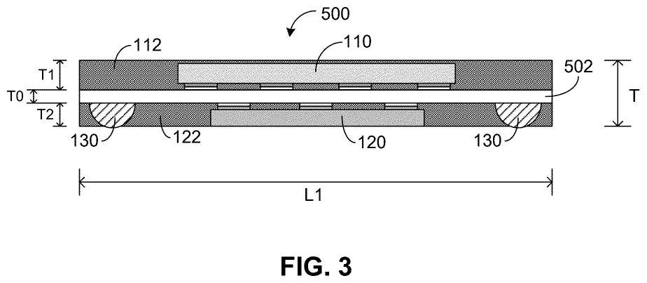

FIG. 3 shows a side view of an example packaged module 500 that includes a thin packaging substrate 502 such as the thin packaging substrate 502 of FIGS. 1 and 2. In FIG. 3, the example packaged module 500 is shown to further include a first side having a first component 110 such as a first die mounted on a first side of the packaging substrate 502, and a second side having a second component 120 such as a second die mounted on a second side of the packaging substrate 502. On the first side, a first mold structure 112 is shown to be provided to encapsulate some or all of the first component 110; and on the second side, a second mold structure 122 is shown to be provided to encapsulate some or all of the second component 120.

In the example of FIG. 3, the example packaged module 500 is shown to further include a plurality of mounting structures such as ball-shaped structures 130. The second mold structure 122 is shown to encapsulate most of such ball-shaped structures 130 while exposing respective mounting portions to allow mounting of the packaged module 500 onto, for example, a circuit board.

Configured in the foregoing manner, the example packaged module 500 is implemented as a dual-side molded module. It is noted that in some embodiments, a packaging module having a thin packaging substrate as described herein may or may not include dual-side mold structures.

It is noted that use of a thin packaging substrate to form a packaged module poses a number of challenges such as mechanical and/or thermal challenges. Described herein are examples of fabrication processes, resulting assemblies and products related to use of thin packaging substrates where some or all of the foregoing challenges can be overcome or have their effects sufficiently reduced.

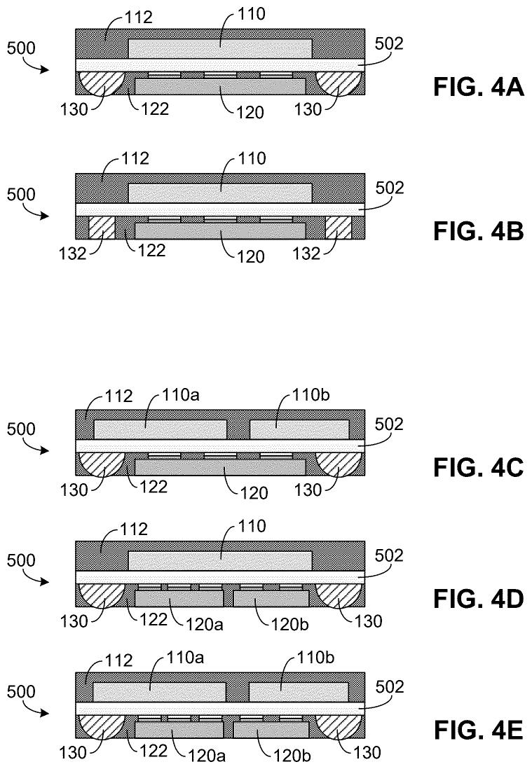

Described herein are various examples related to dual-sided modules that can be implemented for electronic applications such as radio-frequency (RF) applications. FIGS. 4A to 4E show examples of dual-sided (DS) modules 500 where each includes a thin substrate 502 with a first side (e.g., an upper side when oriented as shown) and a second side (e.g., an underside). In some embodiments, such a thin substrate can be any one of the examples described herein in reference to FIGS. 1 to 3.

On the first side of the substrate 502, one or more components 110 is/are shown to be mounted. Such component(s) can be, for example, one or more die, one or more non-die components, or some combination thereof for contributing to RF functionality of the module 500. In FIGS. 4A, 4B and 4D, each module 500 is shown to have one component 110. In FIGS. 4C and 4E, each module 500 is shown to have two components 110a, 110b. Examples of such component(s) (110) are provided herein in greater detail.

On the second side of the substrate 502, one or more components 120 is/are shown to be mounted. Such component(s) can be, for example, one or more die, one or more non-die components, or some combination thereof for contributing to RF functionality of the module 500. In FIGS. 4A, 4B and 4C, each module 500 is shown to have one component 120. In FIGS. 4D and 4E, each module 500 is shown to have two components 120a, 120b. Examples of such component(s) (120) are provided herein in greater detail.

Based on the foregoing examples of FIGS. 4A to 4E, it will be understood that a dual-sided module having one or more features as described herein can include one or more components on one side, and one or more components on the other side of a substrate (502).

Referring to FIGS. 4A to 4E, each module 500 is shown to have a first mold structure 112 formed on the first side of the substrate 502, and a second mold structure 122 formed on the second side of the substrate 502. Each of the first and second mold structures 112, 122 can be dimensioned to have a desired thickness, such that the overall thickness of the module 500 is determined by the thicknesses of the first and second mold structures 112, 122 and the thickness of the substrate 502.

In the examples of FIGS. 4A to 4E, the first mold structure 112 is shown to be dimensioned to fully encapsulate non-mounting side and lateral sides of the component(s) 110. However, it will be understood that the first mold structure 112 can be dimensioned to expose at least a portion of the component(s) 110.

Similarly, the second mold structure 122 is shown to be dimensioned to expose non-mounting side of the component(s) 120. However, it will be understood that the second mold structure 122 can be dimensioned to fully encapsulate non-mounting side and lateral sides of the component(s) 120.

In the examples of FIGS. 4A and 4C to 4E, each module 500 is shown to include ball-shaped structures 130 (e.g., solder balls) configured to provide mounting and electrical connectivity functionalities for the module 500. Such ball-shaped structures 130 are shown to be mostly encapsulated by the second mold structure 122, but with respective mounting surfaces exposed to allow the foregoing mounting and electrical connectivity functionalities. Various examples hereinafter are described in the context of modules having such ball-shaped structures.

However, and as shown in the example of FIG. 4B, a module 500 having one or more features as described herein can utilize other structures such as metal post structures 132 (e.g., copper posts) configured to provide mounting and electrical connectivity functionalities for the module 500. Such metal post structures 132 are shown to be mostly encapsulated by the second mold structure 122, but with respective mounting surfaces exposed to allow the foregoing mounting and electrical connectivity functionalities.

In some embodiments, the substrate 502 in the examples of FIGS. 4A to 4E can be or include a packaging substrate described herein in reference to FIGS. 1 to 3. Examples related to methods for fabricating dual-sided modules with such packaging substrates are described herein in greater detail.

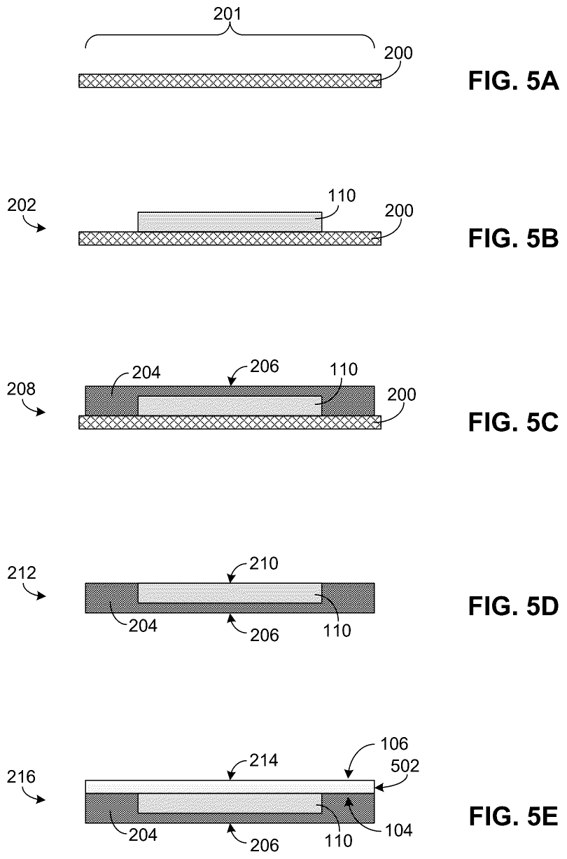

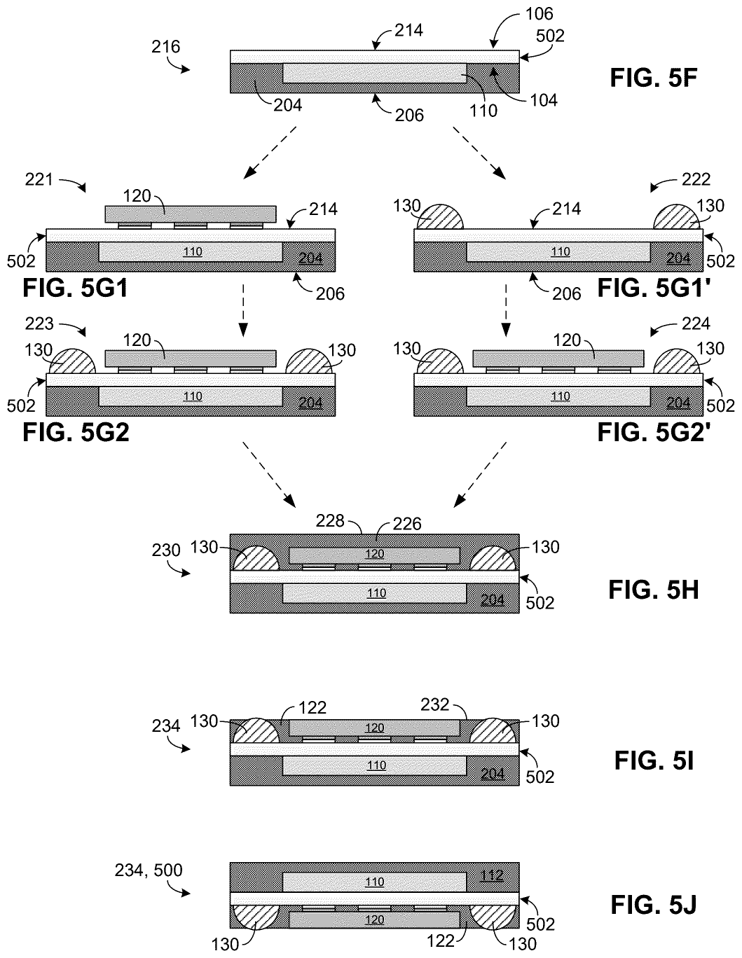

FIGS. 5A to 5J show various stages of a process that can be utilized to fabricate a dual-sided module such as any one of the modules 500 of FIGS. 4A to 4E. In the example process of FIGS. 5A to 5J, ball-shaped structures (e.g., solder balls) are utilized to provide mounting and electrical connectivity functionalities for the resulting module; however, and as discussed above, other structures such as metal posts structures 132 of FIG. 4B, can also be utilized.

FIG. 5A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 5B shows a stage where a component 110 is shown to be mounted on one side of the metal carrier 200 so as to form an assembly 202. In some embodiments, such a component (110) can be any one of components on the non-mounting side of dual-sided modules as described herein.

FIG. 5C shows a stage where a mold structure 204 is formed to partially or fully encapsulate the component 110 and define a surface 206, so as to form an assembly 208. In some embodiments, the mold structure 204 may or may not remain the same until the end of the fabrication process. If the former, the surface 206 may end up being the upper surface (when viewed as in FIGS. 4A to 4E) of the mold structure 112 on the non-mounting side of the respective module 500. If the latter, the mold structure 204 may be thinned such that the original surface 206 is removed to form a new surface.

FIG. 5D shows a stage where the metal carrier 200 in the assembly 208 of FIG. 5C is removed to provide a surface 210, so as to form an assembly 212. In some embodiments, such a removal of the metal carrier 200 can be achieved by a debonding process.

FIG. 5E shows a stage where a packaging substrate 502 is formed or provided on the surface (210 in FIG. 5D, resulting from the removal of the metal carrier 200) of the assembly 212, so as to form an assembly 216. In some embodiments, the packaging substrate 502 can include multiple layers, and such packaging substrate can be provided on the assembly 212 in a fully pre-fabricated form, be built on the assembly 212 based on a partially pre-fabricated form, or be built layer-by-layer on the assembly 212.

In the example of FIG. 5E, it is noted that the packaging substrate 502 includes a first side 104 and a second side 106. The first side 104 is attached to the assembly 212 (FIG. 5D), and such an assembly (212) can form one side of a dual-sided module. The second side 106 of the packaging substrate 502 is shown to be exposed, such that the assembly 216 of FIG. 5E provides a platform with a surface 214 for formation of the other side of the corresponding dual-sided module.

FIG. 5F shows the same assembly 216 as in FIG. 5E. FIG. 5G1 and 5G2 show an example of how a component 120 and ball-shaped structures 130 can be implemented on the surface 214 of the assembly 216 of FIG. 5F, and FIG. 5G1′ and 5G2′ show another example of how a component 120 and ball-shaped structures 130 can be implemented on the surface 214 of the assembly 216 of FIG. 5F.

In the first example, FIG. 5G1 shows a stage where a component 120 is mounted on the surface 214 of the assembly 216 of FIG. 5F, so as to form an assembly 221. In some embodiments, such a mounting process can include formation of mounting pads on the surface of the packaging substrate 502.

Continuing with the first example, FIG. 5G2 shows a stage where ball-shaped structures 130 are implemented on the surface 214 of the assembly 221 of FIG. 5G1, so as to form an assembly 223.

In the second example, FIG. 5G1′ shows a stage where ball-shaped structures 130 are implemented on the surface 214 of the assembly 216 of FIG. 5F, so as to form an assembly 222.

Continuing with the second example, FIG. 5G2′ shows a stage where a component 120 is mounted on the surface 214 of the assembly 222 of FIG. 5G1′, so as to form an assembly 224. In some embodiments, such a mounting process can include formation of mounting pads on the surface of the packaging substrate 502.

FIG. 5H shows a stage where a mold structure 226 is formed to encapsulate the component 120 and the ball-shaped structures 130 of the assembly 223 or 224, so as to form an assembly 230. In such an assembly (230), the mold structure 226 defines a surface 228.

FIG. 5I shows a stage where the mold structure 226 is thinned to remove the original surface 228 and provide a new surface 232, so as to form an assembly 234. In some embodiments, such a thinning process can include a grinding operation. In some embodiments, the new surface 232 resulting from the thinning operation can expose the non-mounting side of the component 120 (mounting side of the assembly 234) as well as mounting portions of the ball-shaped structures 130.

FIG. 5J shows the same assembly 234 as in FIG. 5I, except that in FIG. 5J, the assembly is oriented similar to the example modules of FIGS. 4A to 4E, with an assumption that the assembly 234 will be mounted as shown on another mounting surface. The assembly 234 of FIG. 5J is substantially the same as the example of FIG. 4A; thus, it is also indicated as a dual-sided module 500.

In the examples of FIGS. 4A to 4E and 5A to 5J, dual-sided modules 500 are depicted as having a component 110 on the first side of a respective substrate 502, and a first mold structure 112 being dimensioned to cover the non-mounting side of the component 110.

It is noted that in some embodiments, a dual-sided module having one or more features as described herein can include a component on the first side of a substrate and a first mold structure, such that the non-mounting side of the component is at least partially exposed.

For example, in some embodiments, the first mold structure can be thinned to partially or fully expose the original non-mounting side of a component (e.g., a die) on the first side of a substrate. In such a configuration, overall thickness on the first side of the substrate can be approximately the height of the original mounted component.

In another example, in some embodiments, the first mold structure can be thinned, and such a thinning operation (e.g., a grinding operation) can also remove material on the non-mounting side of a component (e.g., a die) on the first side of a substrate. Accordingly, the thinned first mold structure can expose the thinned surface (e.g., ground surface) of the component. In such a configuration, overall thickness on the first side of the substrate can be selected to be less than the height of the original mounted component, since a portion of the component may be removed.

It will be understood that in some embodiments, and as described herein, a dual-sided module having one or more features as described herein can include a component on the second side of a substrate and a second mold structure, such that the non-mounting side of the component is at least partially exposed similar to the foregoing configurations of component and first mold structure on the first side of a substrate.

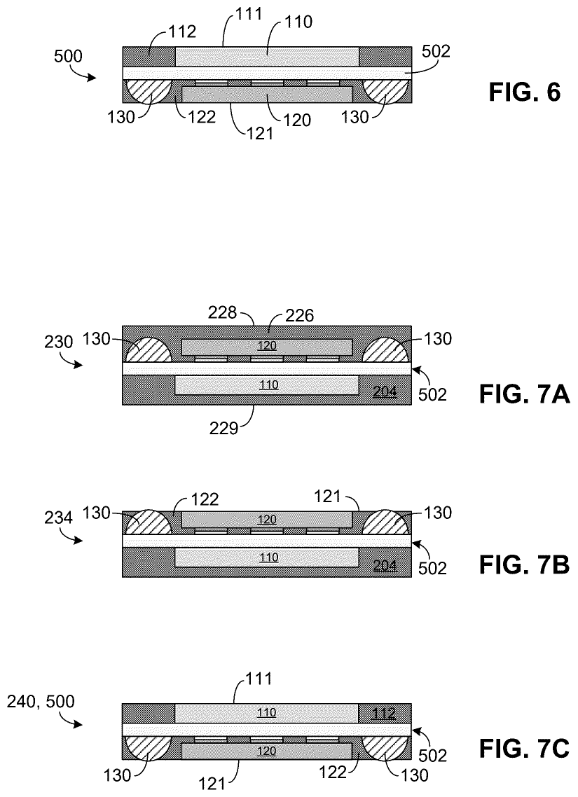

FIG. 6 shows a dual-sided module 500 that includes the foregoing configuration where a first mold structure is dimensioned to expose at least a portion of the non-mounting side of a component on the first side of a substrate. More particularly, the dual-sided module 500 of FIG. 6 is shown to include a packaging substrate 502 as described herein. The packaging substrate 502 is shown to have a first side and a second side, such that one or more components 110 is/are mounted on the first side of the substrate 502, and one or more components 120 is/are mounted on the second side of the substrate 502.

Referring to FIG. 6, the module 500 is shown to have a first mold structure 112 formed on the first side of the substrate 502, and a second mold structure 122 formed on the second side of the substrate 502. The first mold structure 112 is shown to have a selected thickness to expose at least a portion of the non-mounting side of the component 110 mounted on the first side of the substrate 502. In some embodiments, an exposed surface 111 on the non-mounting side of the component 110 can result from a portion of the component 110 being removed (e.g., by grinding) during a thinning process (e.g., grinding process) that thins the first mold structure 112.

Similarly, the second mold structure 122 is shown to have a selected thickness to expose at least a portion of the non-mounting side of the component 120 mounted on the second side of the substrate 502. In some embodiments, an exposed surface 121 on the non-mounting side of the component 120 can result from a portion of the component 120 being removed (e.g., by grinding) during a thinning process (e.g., grinding process) that thins the second mold structure 122.

FIGS. 7A to 7C show an example process that can be utilized to fabricate the dual-sided module 500 of FIG. 6. In FIG. 7A, an assembly 230, such as the assembly 230 of FIG. 5H, can be formed or provided.

FIG. 7B shows a stage where a mold structure 226 is thinned to remove the original surface 228 (FIG. 7A) and provide a new surface 121, so as to form an assembly 234, similar to the example of FIG. 5I (with the mold structure indicated as 122). In some embodiments, such a thinning process can include a grinding operation. In some embodiments, the new surface 121 resulting from the thinning operation can expose the non-mounting side of the component 120 (mounting side of the assembly 234) as well as mounting portions of the ball-shaped structures 130.

FIG. 7C shows a stage where a mold structure 204 is thinned to remove the original surface 229 (FIG. 7A) and provide a new surface 111, so as to form an assembly 240. In some embodiments, such a thinning process can include a grinding operation. In some embodiments, the new surface 111 resulting from the thinning operation can expose the non-mounting side of the component 110 (non-mounting side of the assembly 240). In FIG. 7C, the assembly 240 is similar to the example of FIG. 6; thus, it is also indicated as a dual-sided module 500 and the corresponding first mold structure is indicated as 112.

FIGS. 5A to 5J and 7A to 7C show various stages of one module during its fabrication process. It will be understood that in some embodiments, some or all of such a fabrication can be performed for multiple units in an array format. Examples related to such array format fabrication processes are described herein in greater detail.

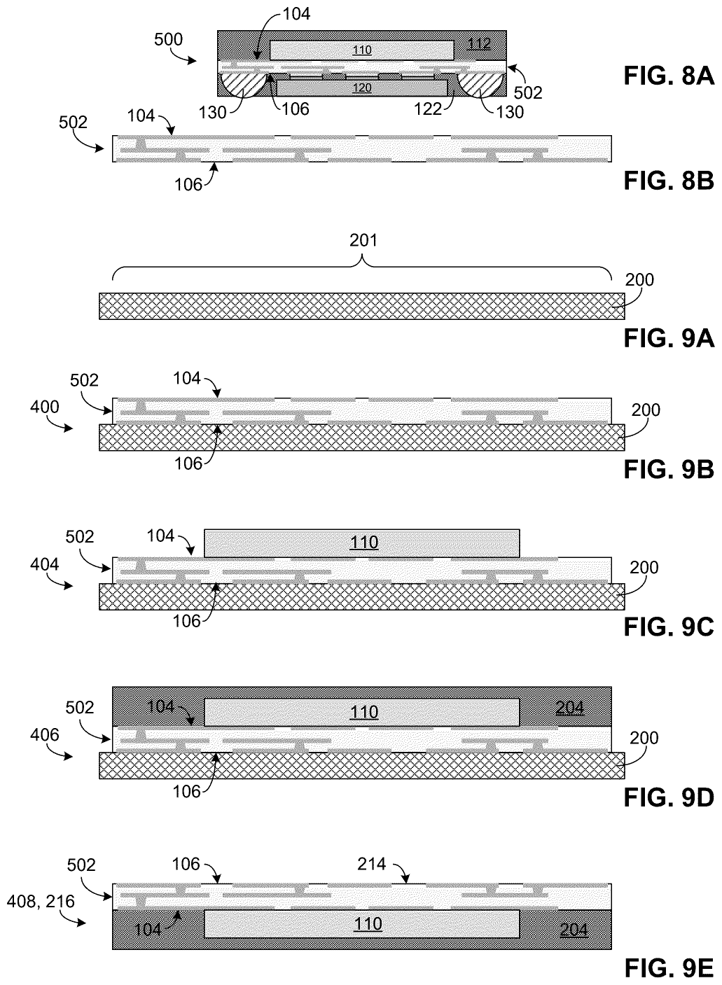

FIG. 8A show a dual-sided module 500 that is similar to the module 500 of FIG. 5J. In FIG. 8A, the dual-sided module 500 is shown to include a packaging substrate 502 having examples of metal layers/traces, vias and pads for providing electrical connections including those associated with the first and second components 110, 120. In some embodiments, such electrical connections can include redistribution of electrical connections. FIG. 8B shows an enlarged view of the packaging substrate 502 by itself.

Referring to FIGS. 8A and 8B, a first side 104 of the packaging substrate 502 is shown to be configured to have the first component 110 mounted thereto, and a second side 106 of the packaging substrate 502 is shown to be configured to have the second component 120 mounted thereto. Thus, and depending on the first and second components 110, 120, first and second sides 104, 106 of the packaging substrate 502 may or may not be the same.

It is noted that in the examples of FIGS. 5A to 5J, and more particularly to FIGS. 5C and 5E, the first side of a module being fabricated can be built first on a carrier (assembly 208 in FIG. 5C), and then a packaging substrate can be provided or constructed on such a first-side portion after removal of the carrier to provide an assembly (216 in FIG. 5E) that acts as a platform for building the second side of the module being fabricated.

In some embodiments, a dual-sided module having one or more features as described herein can be fabricated by a process where a thin substrate is provided or constructed on a carrier before building of any side portion (e.g., first side portion) of the module. FIGS. 9A to 9E show various stages of such a process.

FIG. 9A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 9B shows a stage where a thin substrate 502 is formed or provided on the carrier 200, so as to form an assembly 400. In some embodiments, the thin substrate 502 can include a plurality of layers, and such thin substrate can be provided on the carrier 200 in a fully pre-fabricated form, be built on the carrier 200 based on a partially pre-fabricated form, or be built layer-by-layer on the carrier 200.

In the example of FIG. 9B, it is noted that the thin substrate 502 includes a first side 104 and a second side 106. The second side 106 is shown to be attached to the carrier 200, and the first side 106 is shown to be exposed for building of a first-side portion of a dual-sided module being fabricated.

It will be understood that in some embodiments, the thin substrate 502 can be formed or provided so that an assembly similar to the assembly 400 of FIG. 9B can be implemented where the first side 104 is attached to the carrier 200, and the second side 106 is exposed for building of a second-side portion of a dual-sided module being fabricated.

FIG. 9C shows a stage where a component 110 is mounted on the first side of the thin substrate 502 so as to form an assembly 404. In some embodiments, such a component (110) can be any one of components on the non-mounting side of dual-sided modules as described herein.

FIG. 9D shows a stage where a mold structure 204 is formed to partially or fully encapsulate the component 110 so as to form an assembly 406. In some embodiments, the mold structure 204 may or may not remain the same until the end of the fabrication process.

FIG. 9E shows a stage where the carrier 200 in the assembly 406 of FIG. 9D is removed to expose the second side 106 of the thin substrate 502, so as to form an assembly 408. In some embodiments, the assembly 408 can be similar to the assembly 216 of FIGS. 5E and 5F. Thus, in FIG. 9E, the assembly 408 is also indicated as 216, and the second side 106 also provides a surface 214 of the assembly 408/216. In some embodiments, subsequent module fabrication steps can be similar to the examples of FIGS. 5F to 5J.

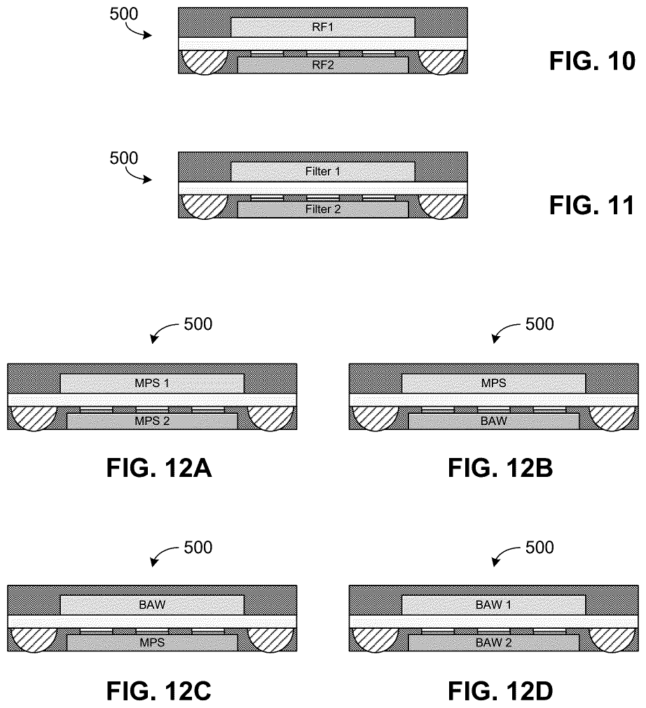

FIG. 10 shows that in some embodiments, a dual-sided module having one or more features as described herein can include a first component (110 in FIGS. 4A to 4E) implemented as a first radio-frequency (RF) device (RF1), and a second component (120 in FIGS. 4A to 4E) implemented as a second radio-frequency (RF) device (RF2). In some embodiments, each of the first and second RF devices can be implemented as a flip-chip device or be configured to provide flip-chip mounting functionality.

FIG. 11 shows that in some embodiments, the first RF device (RF1) of FIG. 10 can be a first filter device (Filter 1), and the second RF device (RF2) of FIG. 10 can be a second filter device (Filter 2).

In some embodiments, each of the filter devices of FIG. 11 can be implemented as an acoustic filter. Such an acoustic filter can be, for example, a multilayer piezoelectric substrate (MPS) filter or a bulk acoustic wave (BAW) filter. In the context of such example acoustic filters, FIGS. 12A to 12D show non-limiting examples where first and second components (110, 120) of a dual-sided module can be implemented as different combinations of MPS and BAW filters.

For example, FIG. 12A shows that in some embodiments, a dual-sided module 500 having one or more features as described herein can have its first component implemented as a first MPS filter (MPS 1) and second component implemented as a second MPS filter (MPS 2).

In another example, FIG. 12B shows that in some embodiments, a dual-sided module 500 having one or more features as described herein can have its first component implemented as an MPS filter (MPS) and second component implemented as a BAW filter (BAW).

In yet another example, FIG. 12C shows that in some embodiments, a dual-sided module 500 having one or more features as described herein can have its first component implemented as a BAW filter (BAW) and second component implemented as an MPS filter (MPS).

In yet another example, FIG. 12D shows that in some embodiments, a dual-sided module 500 having one or more features as described herein can have its first component implemented as a first BAW filter (BAW 1) and second component implemented as a second BAW filter (BAW 2).

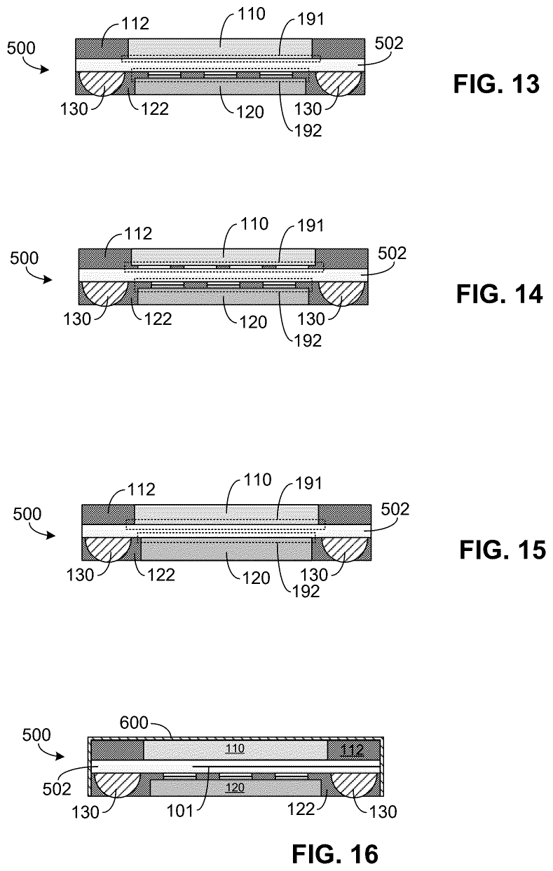

FIG. 13 shows a dual-sided module 500 having one or more features as described herein, where a first component 110 is coupled to a first side of a packaging substrate 502, and a second component 120 is coupled to a second side of the packaging substrate 502. The coupling between first component 110 and the first side of the packaging substrate 502 is shown to be provided by a first interconnect 191, and the coupling between second component 120 and the second side of the packaging substrate 502 is shown to be provided by a second interconnect 192.

FIG. 13 shows that in some embodiments, the first interconnect 191 can be configured such that no gap is present between the first component 110 and the first side of the packaging substrate 502. Such a configuration can be provided by patterning the mounting side of the first component 110 and the first side of the packaging substrate 502 so that the first component 110 can be mated directly with the first side of the packaging substrate 502 (e.g., in FIG. 5B and FIG. 9B), thereby providing a no-gap interconnect configuration therebetween.

FIG. 13 also shows that in some embodiments, the second interconnect 192 can be configured such that the second component 120 is mounted to the second side of the packaging substrate 502 (e.g., in FIG. 5G1 and FIG. 5G2′) utilizing a surface mount technology (SMT) process. With such a mounting configuration, a gap is typically present between the second component 120 and the second side of the packaging substrate 502. In some embodiments, such a gap can be filled with an underfill material. In some embodiments, such an underfill can be achieved during a molding process (e.g., in FIG. 5H), such that the underfill is formed from the same material as the second mold structure 122.

FIG. 14 shows that in some embodiments, a first interconnect 191 can be configured such that a first component 110 of a dual-sided module 500 is mounted to a first side of a packaging substrate 502 utilizing a surface mount technology (SMT) process. With such a mounting configuration, a gap is typically present between the first component 110 and the first side of the packaging substrate 502. In some embodiments, such a gap can be filled with an underfill material. In some embodiments, such an underfill can be achieved during a molding process, such that the underfill is formed from the same material as the first mold structure 112.

In the example of FIG. 14, a second interconnect 192 can be similar to the example of FIG. 13.

FIG. 15 shows that in some embodiments, a first interconnect 191 of a dual-sided module 500 can be similar to the example of FIG. 13, and a second interconnect 192 of the dual-sided module 500 can also be implemented to provide a no-gap interconnect configuration. In some embodiments, such a second interconnect (192) can be achieved by patterning the mounting side of the second component 120 and the second side of the packaging substrate 502 so that the second component 120 can be mated directly with the second side of the packaging substrate 502, thereby providing a no-gap interconnect configuration therebetween.

It will be understood that in some embodiments, a dual-sided module having one or more features as described herein can also be implemented such that a first interconnect (191) is similar to the example of FIG. 14 to provide a gap interconnect configuration, and a second interconnect (192) is similar to the example of FIG. 15 to provide a no-gap interconnect configuration.

In some embodiments, a dual-sided module having one or more features as described herein can include an electromagnetic (EM) shielding feature. For example, FIG. 16 shows a dual-sided module 500 fabricated as described herein. The dual-sided module 500 of FIG. 16 is shown to further include a conformal shielding layer 600, formed from electrically conductive material, that covers the non-mounting side (e.g., the upper side when viewed as shown) and side walls.

In the example of FIG. 16, the conformal shielding layer 600 can be electrically connected to an electrical ground plane 101. In some embodiments, such an electrical connection can be achieved through one or more of the side walls. In some embodiments, the ground plane 101 can be a part of the packaging substrate 502 of the module 500.

In some embodiments, formation of the foregoing conformal shielding layer 600 can be achieved on singulated dual-sided modules, such as singulated modules resulting from an array-format fabrication process.

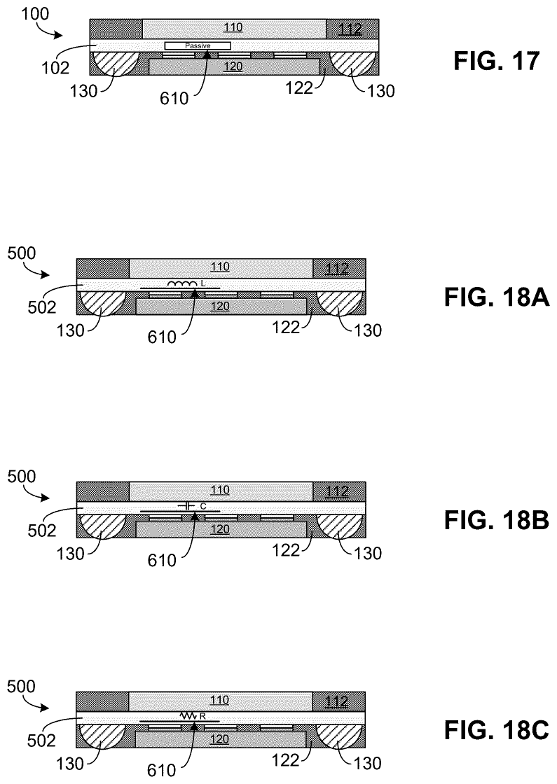

FIG. 17 shows that in some embodiments, a dual-sided module 500 having one or more features as described herein can include a passive circuit element 610 implemented as a part of a packaging substrate 502. In some embodiments, such a passive element can be implemented as one or more features printed on one or more of a plurality of layers of the packaging substrate 502.

For example, FIG. 18A shows that in some embodiments, a dual-sided module 500 having one or more features as described herein can include an inductor 610 having inductance L implemented as a part of a packaging substrate 502. In some embodiments, such an inductor can be implemented as a printed metal trace on one or more of a plurality of layers of the packaging substrate 502.

In another example, FIG. 18B shows that in some embodiments, a dual-sided module 500 having one or more features as described herein can include a capacitor 610 having capacitance C implemented as a part of a packaging substrate 502. In some embodiments, such a capacitor can be implemented as one or more printed metal features on one or more of a plurality of layers of the packaging substrate 502.

In yet another example, FIG. 18C shows that in some embodiments, a dual-sided module 500 having one or more features as described herein can include a resistor 610 having resistance R implemented as a part of a packaging substrate 502. In some embodiments, such a resistor can be implemented as one or more printed features on one or more of a plurality of layers of the packaging substrate 502.

In many radio-frequency (RF) applications, it is desirable to provide reduced footprints in packaged modules that include radio-frequency (RF) filters such as filters based on acoustic wave devices. In some embodiments, a packaged module as described herein can include one or more of such filters and one or more passive elements for supporting (e.g., matching) such filter(s).

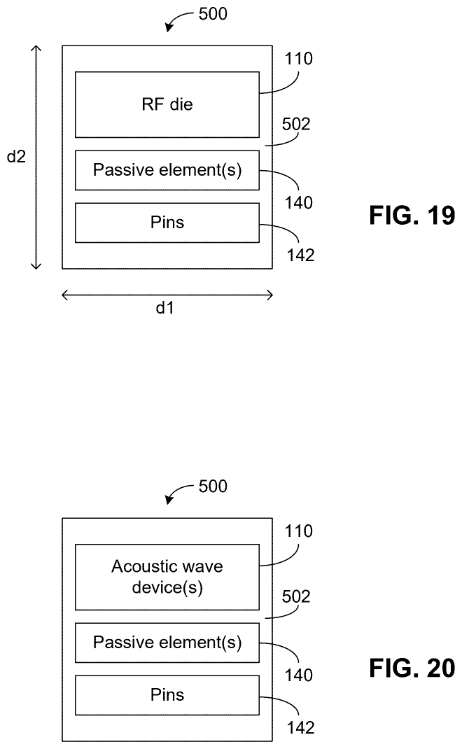

FIG. 19 depicts a packaged module 500 having a packaging substrate 502 as described herein, and an RF die 110 implemented on the substrate 502, and a plurality of pins 142 implemented on the substrate 502 (e.g., on a side opposite from the side with the die 110) to provide mounting and electrical connection functionalities when mounted on a circuit board. In some embodiments, one or more passive elements 140 can be implemented on and/or within the substrate 502. Examples related to the RF die 110, the passive element(s) 140 and the pins 142 are provided herein in greater detail.

In FIG. 19, the packaged module 500 is shown to have lateral dimensions d1 by d2. In some embodiments, one or more features as described herein can allow such dimensions to be reduced while providing various functionalities associated with the RF die 110 and passive element(s) 140.

FIG. 20 shows that in some embodiments, the RF die 110 of FIG. 19 can include acoustic wave device(s). Examples of such acoustic wave devices are provided herein in greater detail.

In some embodiments, the packaging substrate 502 of FIG. 20 can be configured to provide wafer level fan out functionality, with one or more layers of the packaging substrate 502 including respective passive element(s) integrated therein. By integrating such passive element(s) in a three-dimensional manner in the packaging substrate 502, more flexibility in footprint dimensions (e.g., d1 and d2 in FIG. 19) of the packaged module 500 can be provided. For example, either or both of the footprint dimensions d1 and d2 can be reduced.

It is noted that in some embodiments, a packaged module having one or more features as described herein can include a mold structure implemented over a packaging substrate to substantially encapsulate one or more die mounted thereon. In some embodiments, such a mold structure can be formed using a low pressure liquid molding technique. In embodiments where a die being encapsulated is an acoustic wave device; and such a molding technique can provide a significant impact on some or all of size, performance and reliability of the acoustic wave device.

It is noted that while various examples are described herein in the context of RF filter die, one or more features of the present disclosure can also be implemented in other types of die where packaging configuration includes fan out functionality.

In the example context where a die of a packaged module is an RF die such as an acoustic wave based filter, a wafer level fan out packaging configuration with one or more integrated passive elements (e.g., one or more inductors) as described herein can result in the packaged module having lateral dimensions that are similar to or only slightly larger than a conventional packaged module having a similar RF die but without integrated passive element(s).

In some embodiments, some or all of integrated passive element(s) as described herein can be implemented to provide desired quality factor(s) such as high quality factor(s). Thus, implementation of such integrated passive element(s) in a packaged module can provide the foregoing size advantage as well as desired performance characteristics.

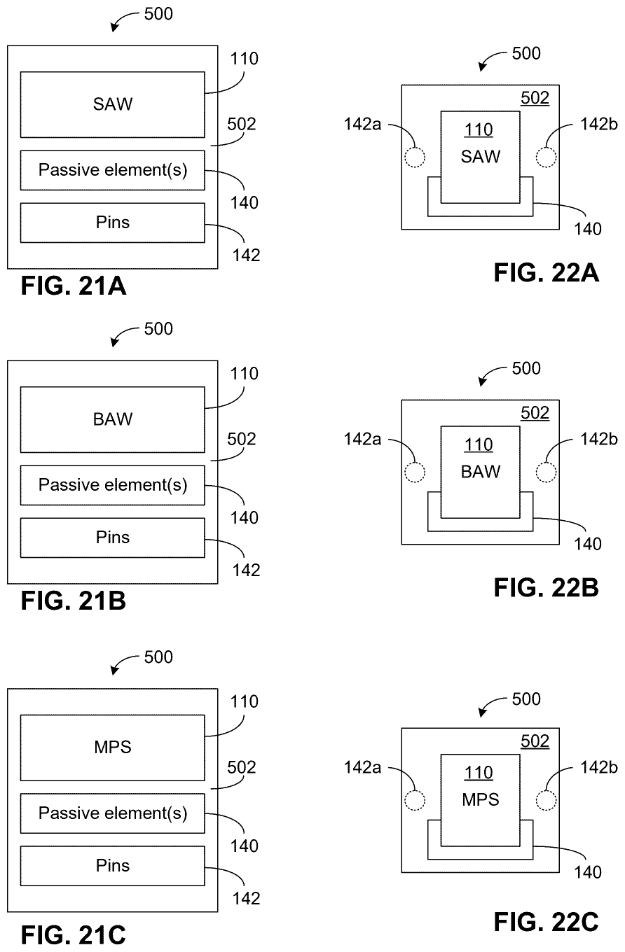

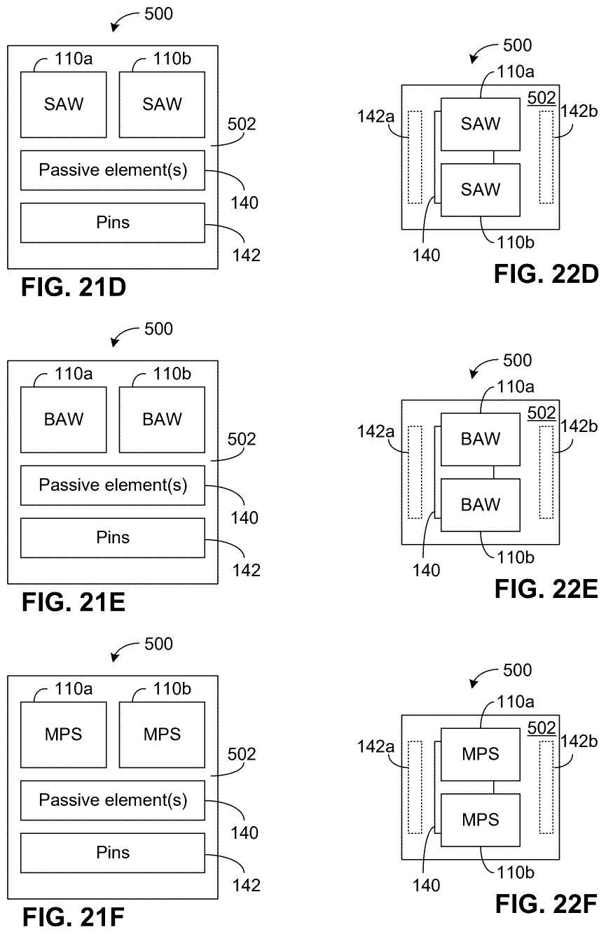

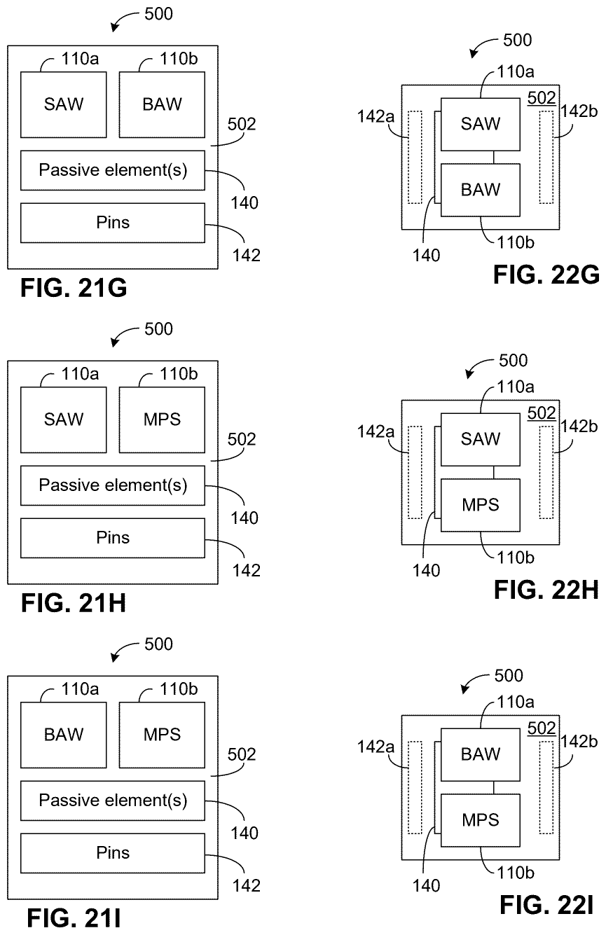

FIGS. 21A to 21I depict block diagrams of non-limiting examples packaged modules each having acoustic wave based filter(s), integrated passive element(s) and connection/mounting pins. FIGS. 22A to 22I depict plan views of the packaged modules of FIGS. 21A to 21I, respectively. It is noted that in each of FIGS. 22A to 22I, one or more integrated passive elements is/are collectively indicated as 140, and such passive element(s) is/are shown to be underneath respective acoustic wave based filter(s) when viewed as shown. It will be understood that lateral area occupied by the passive element(s) 140 may or may not overlap with lateral area occupied by the respective acoustic wave based filter(s).

FIG. 21A shows that in some embodiments, a packaged module 500 can include a packaging substrate 502 that includes one or more integrated passive elements 140. In some embodiments, the packaging substrate 102 can include a plurality of layers, with one or more of such layers including respective passive element(s) 140 integrated therein. The packaged module 500 is shown to further include a surface acoustic wave (SAW) filter 110 and a group of pins 142 implemented with respect to the packaging substrate 502.

FIG. 22A shows that in some embodiments, the packaged module 500 of FIG. 21A can be implemented such that the one or more passive elements 140 is/are on and/or within the packaging substrate 502, the SAW filter 110 is mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the SAW filter 110 is positioned) than to the mounting side of the packaging substrate 502. For example, a passive element can be implemented on an upper layer immediately below the SAW filter 110, or the next layer underneath the upper layer. It will be understood that in some embodiments, a passive element 140 as described herein can be implemented in any layer of the packaging substrate.

FIG. 21B shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include a bulk acoustic wave (BAW) filter 110 and a group of pins 142 implemented with respect to the packaging substrate 502.

FIG. 22B shows that in some embodiments, the packaged module 500 of FIG. 21B can be implemented such that the one or more passive elements 140 is/are on and/or within the packaging substrate 502, the BAW filter 110 is mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the BAW filter 110 is positioned) than to the mounting side of the packaging substrate 502. For example, a passive element can be implemented on an upper layer immediately below the BAW filter 110, or the next layer underneath the upper layer. It will be understood that in some embodiments, a passive element 140 as described herein can be implemented in any layer of the packaging substrate.

FIG. 21C shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include a multilayer piezoelectric substrate (MPS) filter 110 and a group of pins 142 implemented with respect to the packaging substrate 502.

FIG. 22C shows that in some embodiments, the packaged module 500 of FIG. 21C can be implemented such that the one or more passive elements 140 is/are on and/or within the packaging substrate 502, the MPS filter 110 is mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the MPS filter 110 is positioned) than to the mounting side of the packaging substrate 502. For example, a passive element can be implemented on an upper layer immediately below the MPS filter 110, or the next layer underneath the upper layer. It will be understood that in some embodiments, a passive element 140 as described herein can be implemented in any layer of the packaging substrate.

In some embodiments, a packaged module having one or more features as described herein can include a plurality of acoustic wave filters. Such acoustic wave filters can be of same type, different types, or some combination thereof. For example, FIGS. 21D to 21F show examples where two same-type acoustic wave filters are utilized, and FIGS. 21G to 21I show examples where two different types of acoustic wave filters are utilized. Although the foregoing examples are in the context of two acoustic wave filters, it will be understood that more than two acoustic wave filters (e.g., same type, different types, or some combination thereof) can also be utilized in a packaged module as described herein.

FIG. 21D shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include first and second SAW filters 110a, 110b and a group of pins 142 implemented with respect to the packaging substrate 502.

FIG. 22D shows that in some embodiments, the packaged module 500 of FIG. 21D can be implemented such that the one or more passive elements 140 is/are on and/or within the packaging substrate 502, the SAW filters 110a, 110b are mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the SAW filters 110a, 110b are positioned) than to the mounting side of the packaging substrate 502. For example, a passive element can be implemented on an upper layer immediately below the SAW filters 110a, 110b, or the next layer underneath the upper layer. It will be understood that in some embodiments, a passive element 140 as described herein can be implemented in any layer of the packaging substrate.

FIG. 21E shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include first and second BAW filters 110a, 110b and a group of pins 142 implemented with respect to the packaging substrate 502.

FIG. 22E shows that in some embodiments, the packaged module 500 of FIG. 21E can be implemented such that the one or more passive elements 140 is/are on and/or within the packaging substrate 502, the BAW filters 110a, 110b are mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the BAW filters 110a, 110b are positioned) than to the mounting side of the packaging substrate 502. For example, a passive element can be implemented on an upper layer immediately below the BAW filters 110a, 110b, or the next layer underneath the upper layer. It will be understood that in some embodiments, a passive element 140 as described herein can be implemented in any layer of the packaging substrate.

FIG. 21F shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include first and second MPS filters 110a, 110b and a group of pins 142 implemented with respect to the packaging substrate 502.

FIG. 22F shows that in some embodiments, the packaged module 500 of FIG. 21F can be implemented such that the one or more passive elements 140 is/are on and/or within the packaging substrate 502, the MPS filters 110a, 110b are mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the MPS filters 110a, 110b are positioned) than to the mounting side of the packaging substrate 502. For example, a passive element can be implemented on an upper layer immediately below the MPS filters 110a, 110b, or the next layer underneath the upper layer. It will be understood that in some embodiments, a passive element 140 as described herein can be implemented in any layer of the packaging substrate.

FIG. 21G shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include a SAW filter 110a, a BAW filter 110b and a group of pins 142 implemented with respect to the packaging substrate 502.

FIG. 22G shows that in some embodiments, the packaged module 500 of FIG. 21G can be implemented such that the one or more passive elements 140 is/are on and/or within the packaging substrate 502, the SAW and BAW filters 110a, 110b are mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the SAW and BAW filters 110a, 110b are positioned) than to the mounting side of the packaging substrate 502. For example, a passive element can be implemented on an upper layer immediately below the SAW and BAW filters 110a, 110b, or the next layer underneath the upper layer. It will be understood that in some embodiments, a passive element 140 as described herein can be implemented in any layer of the packaging substrate.

FIG. 21H shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include a SAW filter 110a, an MPS filter 110b and a group of pins 142 implemented with respect to the packaging substrate 502.

FIG. 22H shows that in some embodiments, the packaged module 500 of FIG. 21H can be implemented such that the one or more passive elements 140 is/are on and/or within the packaging substrate 502, the SAW and MPS filters 110a, 110b are mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the SAW and MPS filters 110a, 110b are positioned) than to the mounting side of the packaging substrate 502. For example, a passive element can be implemented on an upper layer immediately below the SAW and MPS filters 110a, 110b, or the next layer underneath the upper layer. It will be understood that in some embodiments, a passive element 140 as described herein can be implemented in any layer of the packaging substrate.

FIG. 21I shows that in some embodiments, a packaged module 500 can include a packaging substrate 502 that includes one or more integrated passive elements 140. In some embodiments, the packaging substrate 502 can include a plurality of layers, with one or more of such layers including respective passive element(s) 140 integrated therein. The packaged module 500 is shown to further include a BAW filter 110a, an MPS filter 110b and a group of pins 142 implemented with respect to the packaging substrate 502.

FIG. 22I shows that in some embodiments, the packaged module 500 of FIG. 21I can be implemented such that the one or more passive elements 140 is/are on and/or within the packaging substrate 502, the BAW and MPS filters 110a, 110b are mounted on a first side of the packaging substrate 502, and the group of pins (e.g., 142a, 142b) is implemented on a second side, opposite from the first side, of the packaging substrate 502. In some embodiments, the second side of the packaging substrate 502 can be the mounting side of the packaged module 500, and the first side of the packaging substrate 502 can be the non-mounting side of the packaged module 500.

In some embodiments, at least one the one or more passive elements 140 can be implemented on a respective layer that is closer to the non-mounting side (where the BAW and MPS filters 110a, 110b are positioned) than to the mounting side of the packaging substrate 502. For example, a passive element can be implemented on an upper layer immediately below the BAW and MPS filters 110a, 110b, or the next layer underneath the upper layer. It will be understood that in some embodiments, a passive element 140 as described herein can be implemented in any layer of the packaging substrate.

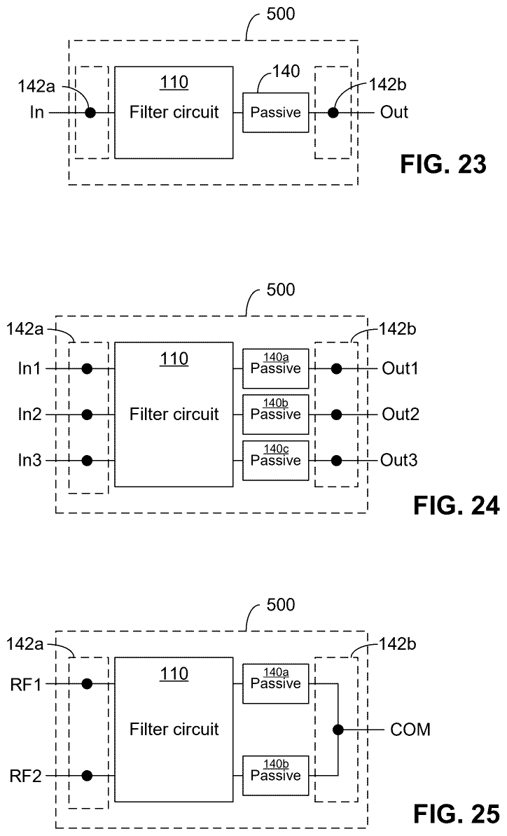

As described herein, a packaged module having one or more acoustic wave filters implemented on a thin packaging substrate with one or more passive elements implemented as part(s) thereof can allow the packaged module to provide high-performance RF filtering functionality in a reduced size format. FIGS. 23 to 25 show non-limiting examples of RF filtering functionalities that can be provided with a packaged module having one or more features as described herein.

For example, FIG. 23 shows that in some embodiments, a packaged module 500 can include a filtering functionality between an input associated with a pin 142a and an output associated with a pin 142b. In such an example, a filter circuit implemented as one or more acoustic wave filter die 110 can be provided to be electrically between the input and output pins 142a, 142b, and one or more passive elements 140 can be implemented relative to the filter circuit 110 to provide, for example, matching functionality.

In the example of FIG. 23, passive element(s) 140 is/are depicted as being implemented on the output sides of the filter circuit 110; however, it will be understood that passive element(s) as described herein can be implemented on an input side and/or on an output side of a filter circuit.

In another example, FIG. 24 shows that in some embodiments, a packaged module 500 can include filtering functionalities between a plurality of inputs associated with pins 142a and a plurality of outputs associated with pins 142b. In such an example, a filter circuit implemented as one or more acoustic wave filter die 110 can be provided to be electrically between the input pins 142a and output pins 142b, and one or more passive elements 140 can be implemented relative to each of at least some of the filtering paths to provide, for example, matching functionality.

For example, and referring to FIG. 24, one or more passive elements can be implemented for each of the filtering paths. In such an example, one or more passive elements 140a can be implemented for a first filtering path between the first input (In1) and the first output (Out1); one or more passive elements 140b can be implemented for a second filtering path between the second input (In2) and the second output (Out2); and one or more passive elements 140c can be implemented for a third filtering path between the third input (In3) and the third output (Out3).

In the example of FIG. 24, passive elements 140a, 140b, 140c are depicted as being implemented on the output sides of the filter circuit 110; however, it will be understood that passive element(s) as described herein can be implemented on an input side and/or on an output side of a filter circuit.

In yet another example, FIG. 25 shows that in some embodiments, a packaged module 500 can include filtering functionalities between a plurality of nodes associated with pins 142a and a common node associated with a pin 142b. In such an example, a filter circuit implemented as one or more acoustic wave filter die 110 can be provided to be electrically between the pins 142a and the pin 142b, and one or more passive elements 140 can be implemented relative to each of at least some of the filtering paths to provide, for example, matching functionality.

For example, and referring to FIG. 25, one or more passive elements can be implemented for each of the filtering paths. In such an example, one or more passive elements 140a can be implemented for a first filtering path between the first node (RF1) and the common node (COM); and one or more passive elements 140b can be implemented for a second filtering path between the second node (RF2) and the common node (COM).

In the example of FIG. 25, passive elements 140a, 140b are depicted as being implemented on the common node (COM) sides of the filter circuit 110; however, it will be understood that passive element(s) as described herein can be implemented on RF node side and/or on a common node side of a filter circuit.

In some embodiments, the filtering architecture of the packaged module 500 can be implemented as a multiplexer configured to provide multiplexing/filtering functionality between a plurality of RF nodes and a common node. In some embodiments, the common node (COM) can be an input node, and the RF nodes (RF1, RF2) can be output nodes for the filter circuit 110. In some embodiments, the RF nodes (RF1, RF2) can be input nodes, and the common node (COM) can be an output node for the filter circuit 110.

Although the example multiplexing architecture of FIG. 25 shows two filtering paths (e.g., as a diplexer), it will be understood that more than two filtering paths can also be implemented in a packaged module as described herein.

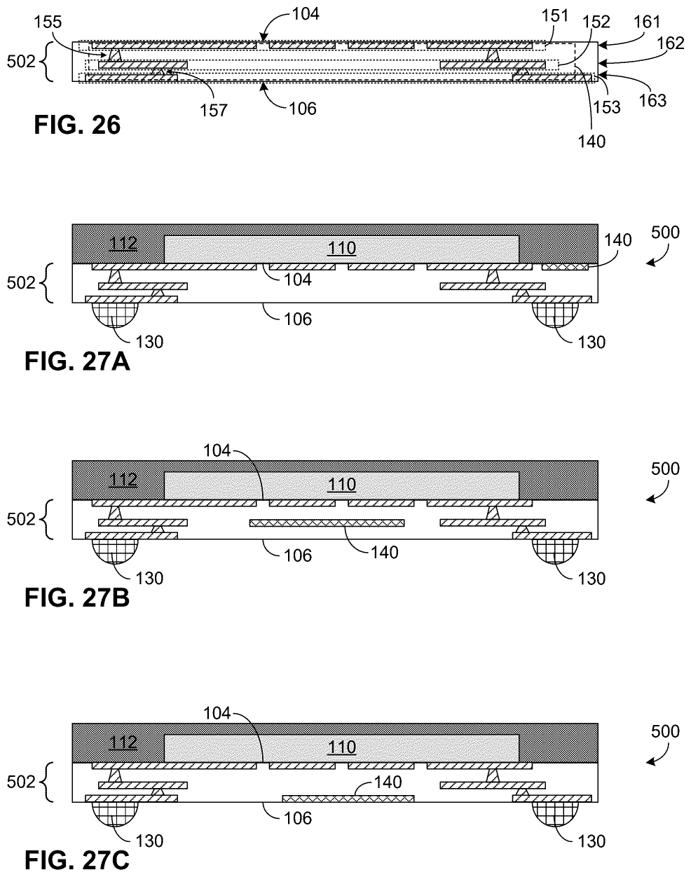

FIG. 26 shows a side sectional view of a thin packaging substrate 502 that can be utilized to form a packaged module as described herein. In some embodiments, such a packaging substrate can include a plurality of layers that provide electrical connections between a die (e.g., acoustic wave filter die) on a first surface 104 of the packaging substrate 502 and mounting pins on a second surface 106 of the packaging substrate 502. In some embodiments, such electrical connections can include a fan-out connection configuration.

In the example of FIG. 26, a plurality of layers with conductive features are shown to provide electrical connections between the first surface 104 and the second surface 106 of the packaging substrate 502. More particularly, a group 151 of conductive features such as metal layers, traces and/or pads are shown to be part of a layer 161 of the packaging substrate 502, such that some or all of the group 151 of conductive features are exposed on the first surface 104 to allow mounting of a die thereon. Similarly, a group 153 of conductive features such as metal layers, traces and/or pads are shown to be part of a layer 163 of the packaging substrate 502, such that some or all of the group 153 of conductive features are exposed on the second surface 106 to allow implementation of connecting/mounting pins thereon.

In FIG. 26, another group 152 of conductive features such as metal layers, traces and/or pads are shown to be part of a layer 162 of the packaging substrate 502, such that the layer 162 is between the above-described layers 161 and 163. Accordingly, three groups of conductive features are provided in the example of FIG. 26. It will be understood that more or less groups of conductive features can be implemented in packaging substrates having one or more features as described herein.

In some embodiments, electrical connections between groups of conductive features can be provided by, for example, conductive vias and respective pads. In the example of FIG. 26, conductive vias 155 are shown to provide electrical connections between the groups of conductive features 151, 152. Similarly conductive vias 157 are shown to provide electrical connections between the groups of conductive features 152, 153.

Referring to the example of FIG. 26, it is noted that the packaging substrate 502 can include a plurality of layers and related structures as described herein in reference to FIGS. 1 and 2.

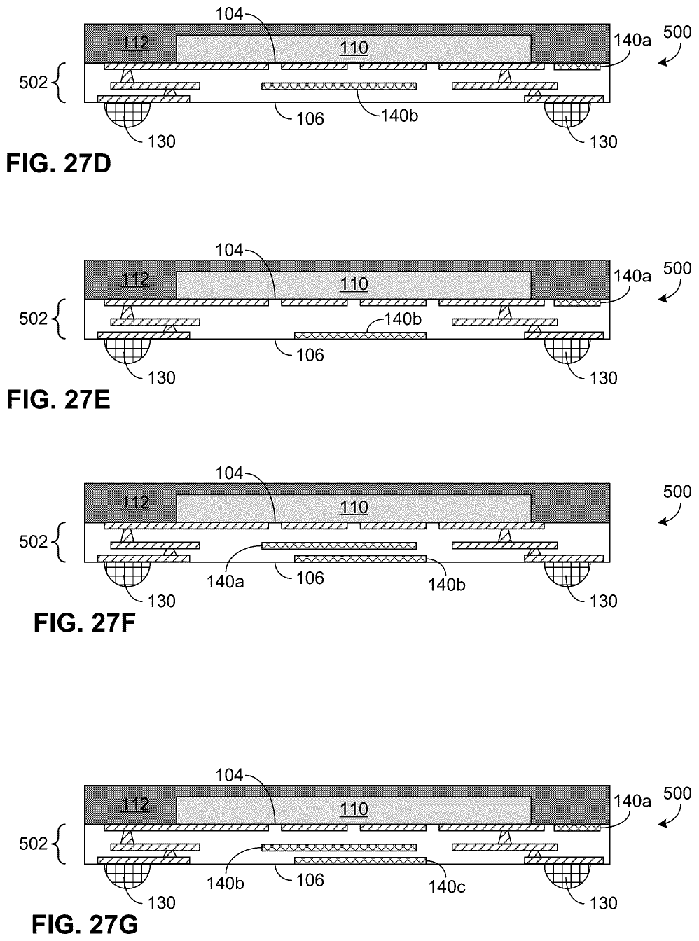

FIG. 26 shows that in some embodiments, the packaging substrate 502 can include one or more passive elements 140 implemented to be in respective layer(s) associated with one or more of the groups of conductive features. FIGS. 27A to 27G show non-limiting examples of such passive elements implemented in packaging substrates of respective packaged modules.

In the examples of FIGS. 27A to 27G, each packaged module 500 is depicted as including an acoustic wave filter die 110 implemented on a first side 104 of a thin packaging substrate 502, and ball-shaped structures (e.g., solder balls) as mounting/connection pins 130 implemented on a second side 106 of the substrate 502. It will be understood that more than one acoustic wave filter die can be implemented on the first side 104 of the substrate 502. Similarly, it will be understood that the pins 130 can be implemented as different type of mounting/connection structures.

FIGS. 27A to 27C show examples where a thin packaging substrate 502 includes a passive element 140 implemented with a group of conductive features. FIG. 27A shows an example where a passive element 140 is implemented with a group of conductive features generally in a layer at or closest to the first surface 104. FIG. 27B shows an example where a passive element 140 is implemented with a group of conductive features generally in a second layer from the first surface 104. FIG. 27C shows an example where a passive element 140 is implemented with a group of conductive features generally in a layer at or closest to the second surface 106.

It is noted that in the examples of FIGS. 27A to 27C, there are three layers with respective groups of conductive features, such that the configurations of FIGS. 27A and 27C correspond to a passive element 140 being implemented at or close to each of the first and second surfaces 104, 106, and the configuration of FIG. 27B corresponds to a passive element 140 being implemented at or close to an intermediate layer.

It will be understood that in some embodiments, a thin packaging substrate having one or more features as described herein can have less than or greater than the example three-layer configuration. For example, if there are two layers with respective conductive features, such layers can be implemented at or close to the first and second surfaces 104, 106. In another example, if there are more than three layers with respective conductive features, first and fourth layers can be implemented at or close to the first and second surfaces 104, 106, and second and third layers can be implemented as intermediate layers.

FIGS. 27D to 27F show examples where a thin packaging substrate 502 includes passive elements implemented with groups of conductive features associated with two different layers. FIG. 27D shows an example where a first passive element 140a is implemented with a group of conductive features generally in a layer at or closest to the first surface 104, and a second passive element 140b is implemented with a group of conductive features generally in a second layer from the first surface 104. FIG. 27E shows an example where a first passive element 140a is implemented with a group of conductive features generally in a layer at or closest to the first surface 104, and a second passive element 140b is implemented with a group of conductive features generally in a layer at or closest to the second surface 106. FIG. 27F shows an example where a first passive element 140a is implemented with a group of conductive features generally in an intermediate layer, and a second passive element 140b is implemented with a group of conductive features generally in a layer at or closest to the second surface 106.

FIG. 27G shows an example where a thin packaging substrate 502 includes passive elements implemented with groups of conductive features associated with all layers. For example, and in the context of the three layers of conductive features, FIG. 27G shows a configuration where a first passive element 140a is implemented with a group of conductive features generally in a layer at or closest to the first surface 104, a second passive element 140b is implemented with a group of conductive features generally in an intermediate layer, and a third passive element 140c is implemented with a group of conductive features generally in a layer at or closest to the second surface 106.

In some embodiments, a passive element implemented as part of a thin packaging substrate can include any circuit element that affects a signal in a circuit in a passive manner. Such a passive element can include, for example, an inductor, a resistor, a capacitor, or some combination thereof.

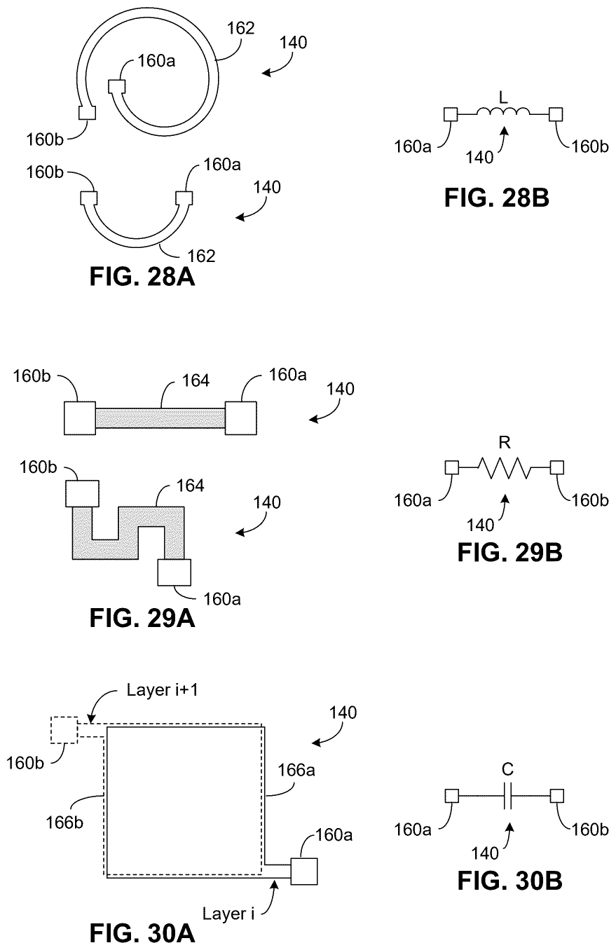

In some embodiments, the foregoing passive element can be formed on a layer of a thin packaging substrate by a process suitable for fabrication of the packaging substrate. For example, FIG. 28A shows two examples of a passive element 140 implemented as an inductor. In one example, a metal trace 162 is shown to form at least one winding between end nodes 160a, 160b. In another example, a metal trace 162 is shown to form a partial winding between end nodes 160a, 160b. FIG. 28B shows a circuit representation of the inductor 140 of FIG. 28A between the nodes 160a, 160b.

In some embodiments, the foregoing metal traces and end nodes can be formed in a manner similar to formation of conductive features such as metal traces. It will be understood that while the foregoing inductor examples are depicted as having curved traces, an inductor can have other shapes to provide a desired inductance between first and second locations of a formed conductive path.

In another example, FIG. 29A shows two examples of a passive element 140 implemented as a resistor. In one example, a straight resistive path 164 is shown to be provided between end nodes 160a, 160b. In another example, a resistive path 164 with bends is shown to be provided between end nodes 160a, 160b. FIG. 29B shows a circuit representation of the resistor 140 of FIG. 29A between the nodes 160a, 160b.

In some embodiments, the foregoing end nodes can be formed in a manner similar to formation of conductive features such as metal traces, and resistive paths can be formed by patterning a layer of resistive material between the end nodes. It will be understood that a resistor can have other shapes to provide a desired resistance between first and second locations.

In yet another example, FIG. 30A shows an example of a passive element 140 implemented as a capacitor. In some embodiments, such a capacitor can be formed by first and second conductive planes 166a, 166b separated by a dielectric material with the first and second conductive planes 166a, 166b being electrically connected to respective nodes 160a, 160b. FIG. 30B shows a circuit representation of the capacitor 140 of FIG. 30A between the nodes 160a, 160b.

In some embodiments, the foregoing conductive planes 166a, 166b and nodes 160a, 160b can be formed in a manner similar to formation of conductive features such as metal traces.

In some embodiments, the separation between the first and second conductive planes 166a, 166b can be provided by the conductive planes being formed in different layers of conductive features. For example, the first conductive plane 166a can be implemented on layer i, and the second conductive plane 166b can be implemented on layer i+1, such that the two conductive planes are separated by, for example, a dielectric layer therebetween.

In some embodiments, the first and second conductive planes 166a, 166b can be provided by the conductive planes being formed on the same given layer of conductive features of the respective substrate. In such an example, the two conductive planes can be separated by a dielectric material.

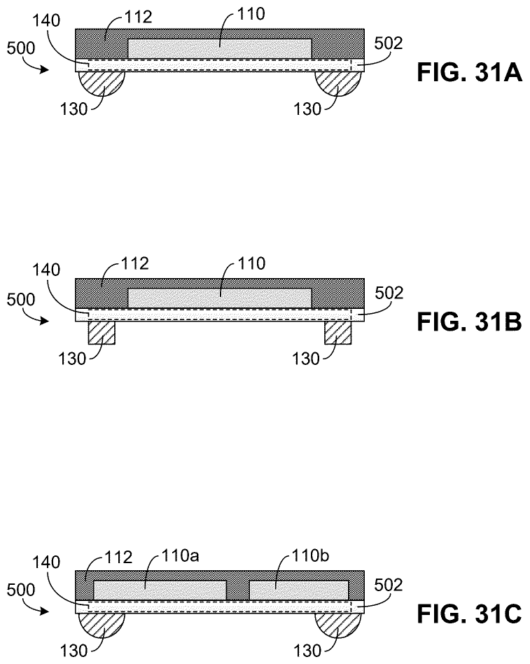

FIGS. 31A and 31B show that packaged modules having one or more features as described herein can be implemented with different types of mounting/connection pins on a mounting side of a thin packaging substrate. For example, FIG. 31A shows that in some embodiments, a plurality of mounting/connection pins are shown to be implemented as ball-shaped structures 130 (e.g., solder balls) on the mounting side of a thin packaging substrate 502. As described herein, such packaging substrate can include one or more passive elements 140, and an acoustic wave filter die 110 and a mold structure 112 can be provided on the non-mounting side of the packaging substrate 502.

In another example, FIG. 31B shows that in some embodiments, a plurality of mounting/connection pins are shown to be implemented as metal post structures 130 (e.g., copper posts) on the mounting side of a thin packaging substrate 502. As described herein, such packaging substrate can include one or more passive elements 140, and an acoustic wave filter die 110 and a mold structure 112 can be provided on the non-mounting side of the packaging substrate 502.

FIG. 31C shows that in some embodiments, a packaged module having one or more features as described herein can include more than one acoustic wave filter provided on a non-mounting side of a thin packaging substrate. For example, in FIG. 31C, first and second acoustic wave filter die 110a, 110b are shown to be provided on a non-mounting side of a thin packaging substrate 502, and a plurality of mounting/connection pins 130 are shown to be provided on a mounting side of the packaging substrate 502. As described herein, such packaging substrate can include one or more passive elements 140.

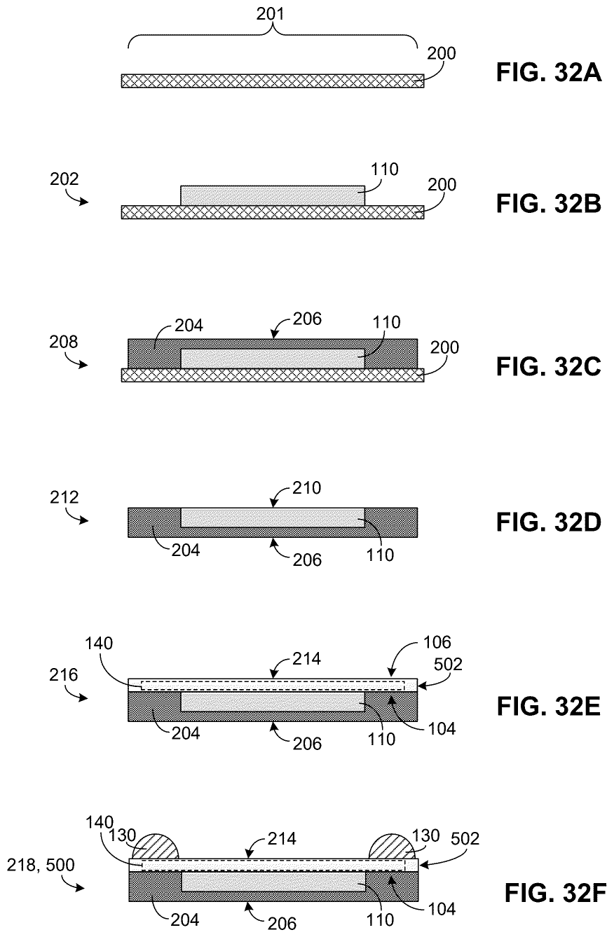

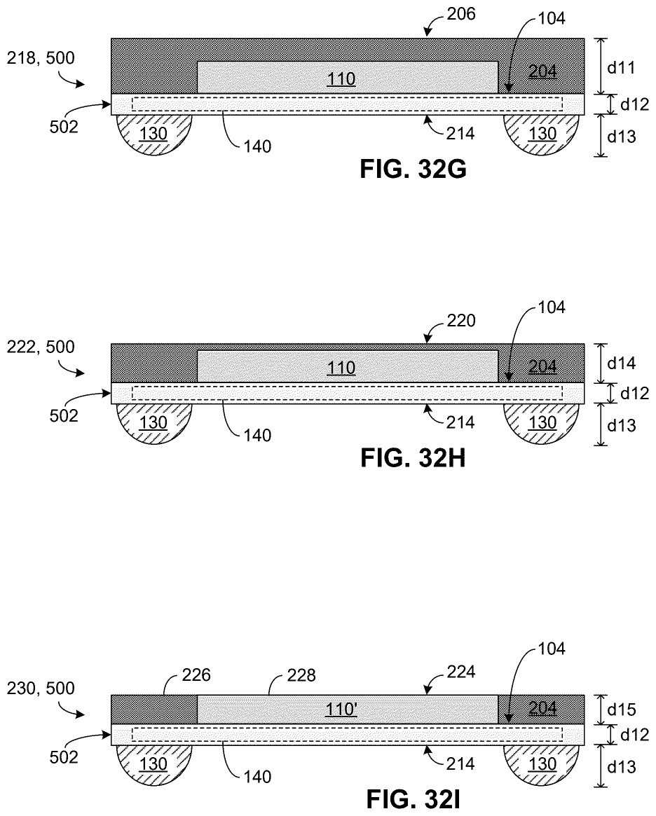

FIGS. 32A to 32F show various stages of a process that can be utilized to fabricate a packaged module having one or more features as described herein. In such an example process, ball-shaped structures (e.g., solder balls) are utilized to provide mounting and electrical connectivity functionalities for the resulting module; however, it will be understood that other structures, such as metal post structures, can also be utilized.

FIG. 32A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 32B shows a stage where a die 110 is shown to be mounted on one side of the metal carrier 200 so as to form an assembly 202. In some embodiments, such a die (110) can be an acoustic wave filter die.

FIG. 32C shows a stage where a mold structure 204 is formed to partially or fully encapsulate the die 110 and define a surface 206, so as to form an assembly 208. In some embodiments, the mold structure 204 may or may not remain the same until the end of the fabrication process. If the former, the surface 206 may end up being the upper surface of the mold structure on the non-mounting side of the respective module. If the latter, the mold structure 204 may be thinned such that the original surface 206 is removed to form a new surface.

In some embodiments, the mold structure 204 of FIG. 32C can be formed using a low pressure liquid molding technique. It is noted that in embodiments where a die being encapsulated is an acoustic wave device; and such a molding technique can provide a significant impact on some or all of size, performance and reliability of the acoustic wave device.

FIG. 32D shows a stage where the metal carrier 200 in the assembly 208 of FIG. 32C is removed to provide a surface 210, so as to form an assembly 212. In some embodiments, such a removal of the metal carrier 200 can be achieved by a debonding process.

FIG. 32E shows a stage where a thin packaging substrate 502 is formed or provided on the surface (210 in FIG. 32D, resulting from the removal of the metal carrier) of the assembly 212, so as to form an assembly 216. In some embodiments, the foregoing packaging substrate 502 can include one or more passive elements 140 as described herein.

In some embodiments, the thin packaging substrate 502 can include a plurality of layers, and such packaging substrate can be provided on the assembly 212 in a fully pre-fabricated form, be built on the assembly 212 based on a partially pre-fabricated form, or be built layer-by-layer on the assembly 212.

In the example of FIG. 32E, it is noted that the packaging substrate 502 includes a first side 104 and a second side 106. The first side 104 is attached to the assembly 212 (FIG. 32D), and the second side 106 of the packaging substrate 502 is shown to be exposed, such that the assembly 216 of FIG. 32E provides a platform with a surface 214 for formation of mounting/connection pins thereon.

FIG. 32F shows a stage where ball-shaped structures 130 are implemented on the surface 214 of the assembly 216 of FIG. 32E, so as to form an assembly 218 that is generally the same as the example packaged module 500 of FIG. 31A. Accordingly, the assembly 218 of FIG. 32E is also indicated as 500.

In some embodiments, the packaged module 500 FIG. 32F can be processed further to provide a desired package thickness. For example, FIG. 32G shows the packaged module 500 of FIG. 32F in an inverted orientation relative to the orientation of FIG. 32F. Further, various example height dimensions are shown: d11 as the thickness of the mold structure 204, d12 as the thickness of the thin packaging substrate 502, and d13 as the height of the ball-shaped structures 130 from the packaging substrate 502. It will be understood that such a height (d13) of the ball-shaped structures 130 can result in an overall height of the packaged module 500 when it is mounted on, for example, a circuit board. Accordingly, one can see that such a mounted height of the packaged module can also be determined by the thickness dimension d11 of the mold structure 204.

FIG. 32H shows that in some embodiments, the mold structure 204 of the packaged module 500 can be thinned to provide a new thickness dimension d14 that is less than d11, to thereby provide an assembly 222. More particularly, material associated with the mold structure 204 can be removed such that the surface 206 (in FIG. 32G) is removed to provide a new surface 220 that is closer to the packaging substrate 502. In some embodiments, such a thinning process can include, for example, a grinding process.

In the example of FIG. 32H, the thinned mold structure 204 is shown to still cover the die 110. However, in some applications, it may be desirable to have the mold structure 204 be thinned further.

FIG. 32I shows that in some embodiments, the mold structure 204 of the packaged module 500 can be thinned further to provide a new thickness dimension d15 that is less than d14 of FIG. 32H, to thereby provide an assembly 230. More particularly, material associated with the mold structure 204, as well as material associated with a back side of the die 110 in some situations, can be removed such that the surface 220 (in FIG. 32H) is removed to provide a new surface 224 for the packaged module 500 that is closer to the packaging substrate 502. In some embodiments, such a thinning process can include, for example, a grinding process.

In the example of FIG. 32I, the new surface 224 is shown to include a new surface 226 of the mold structure 204 and a back side surface 228 of the die 110′. In some embodiments, the new surface 226 of the mold structure 204 and the back side surface 228 of the die 110′are substantially co-planar.

In the example of FIG. 32I, material from the back side of the die (110 in FIG. 32H) may or may not be removed. Accordingly, the back side surface 228 of the die 110′ in FIG. 32I can be the original back side surface of the die (with no die material removed) such that the original back side surface is exposed by the thinning of the mold structure, or a new back side surface resulting from the thinning operation removing materials from the mold structure and the back side of the die.

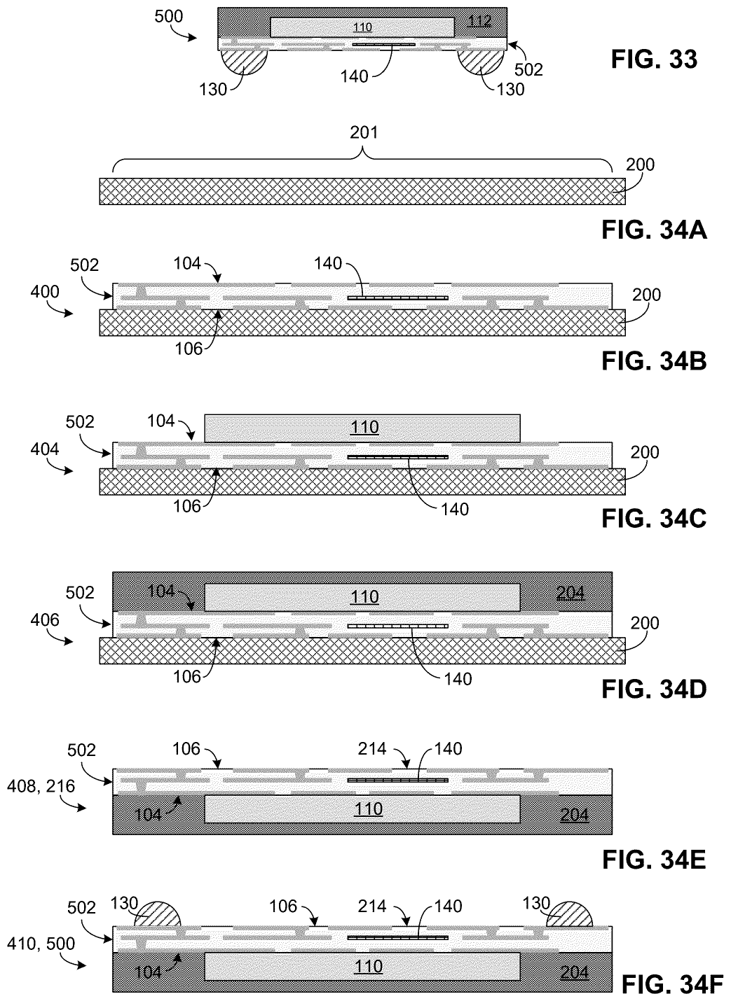

FIG. 33 shows a packaged module 500 that is similar to the module 500 of FIG. 31A. In FIG. 33, a thin packaging substrate 502 of the packaged module 500 is shown to have examples of metal layers/traces, vias and pads for providing electrical connections between a die 110 on one side of the packaging substrate 502 and pins 130 on the other side of the packaging substrate 502.

In FIG. 33, the thin packaging substrate 502 is shown to further include a passive element 140 as described herein. Such packaging substrate can be similar to the packaging substrate 502 of FIG. 26.

Referring to FIGS. 33 and 26, a first side 104 of the packaging substrate 502 is shown to be configured to have the die 110 mounted thereto, and a second side 106 of the packaging substrate 502 is shown to be configured to have implemented thereon a plurality of pins 130.

It is noted that in the examples of FIGS. 32A to 32F, the non-mounting side of a module being fabricated is built first on a carrier (assembly 208 in FIG. 32C), and then a thin packaging substrate is provided or constructed on such a non-mounting-side portion after removal of the carrier to provide an assembly (216 in FIG. 32E) that acts as a platform for processing of the mounting side of the module being fabricated.

In some embodiments, a packaged module having one or more features as described herein can be fabricated by a process where a thin packaging substrate is provided or constructed on a carrier before building of any-side portion (e.g., non-mounting side portion) of the module. FIGS. 34A to 34F show various stages of such a process.

FIG. 34A shows a carrier layer 200 (also referred to herein as a carrier) that can be formed or provided. In some embodiments, such a carrier layer can be implemented as a metal carrier layer (also referred to herein as a metal carrier) having a lateral unit 201 in which a module will be formed.

FIG. 34B shows a stage where a thin packaging substrate 502 is formed or provided on the carrier 200, so as to form an assembly 400. In some embodiments, the foregoing packaging substrate 502 can include one or more passive elements 140 as described herein.

In some embodiments, the thin packaging substrate 502 can include a plurality of layers, and such a packaging substrate can be provided on the assembly 212 in a fully pre-fabricated form, be built on the assembly 212 based on a partially pre-fabricated form, or be built layer-by-layer on the assembly 212.

In the example of FIG. 34B, it is noted that the thin packaging substrate 502 includes a first side 104 (e.g., a non-mounting side) and a second side 106 (e.g., a mounting side). The second side 106 is shown to be attached to the carrier 200, and the first side 106 is shown to be exposed for building of a non-mounting-side portion of a module being fabricated.

It will be understood that in some embodiments, the thin packaging substrate 502 can be formed or provided so that an assembly similar to the assembly 400 of FIG. 34B has the first side 104 is attached to the carrier 200, and the second side 106 is exposed for building of a mounting-side portion of a module being fabricated.

FIG. 34C shows a stage where a die 110 is mounted on the first side of the packaging substrate 502 so as to form an assembly 404. In some embodiments, such a die (110) can include an acoustic wave filter as described herein.

FIG. 34D shows a stage where a mold structure 204 is formed to partially or fully encapsulate the die 110 so as to form an assembly 406. In some embodiments, the mold structure 204 may or may not remain the same until the end of the fabrication process.

FIG. 34E shows a stage where the carrier 200 in the assembly 406 of FIG. 34D is removed to expose the second side 106 of the packaging substrate 502, so as to form an assembly 408. In some embodiments, the assembly 408 of FIG. 34E can be similar to the assembly 216 of FIG. 32E. Thus, in FIG. 34E, the assembly 408 is also indicated as 216, and the second side 106 also provides a surface 214 of the assembly 408/216.

In some embodiments, subsequent module fabrication step(s) can be similar to the example of FIG. 32F. More particularly, FIG. 34F shows a stage where ball-shaped structures 130 are implemented on the surface 214 of the assembly 408 of FIG. 34E, so as to form an assembly 410 that is generally the same as the example packaged module 500 of FIG. 31A. Accordingly, the assembly 410 of FIG. 34E is also indicated as 500.

Various fabrication process examples depicted and described herein show various stages of one module during its fabrication process. It will be understood that in some embodiments, some or all of such a fabrication can be performed for multiple units in an array format.

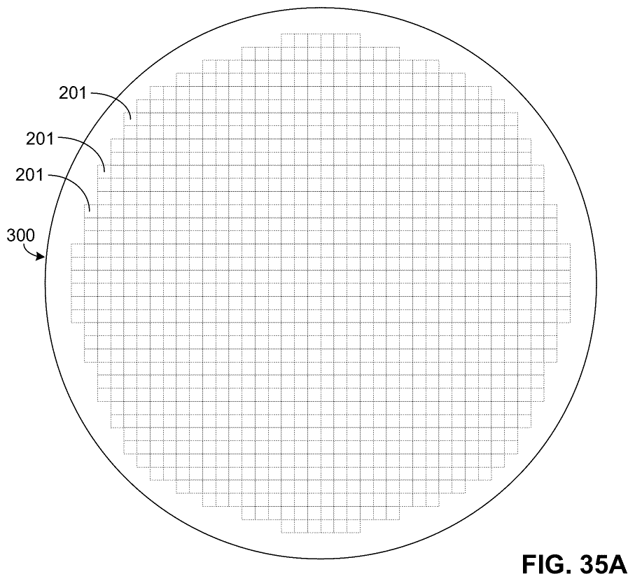

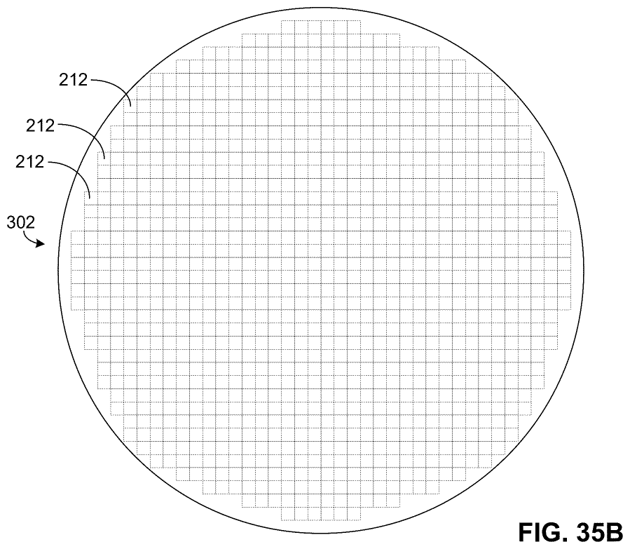

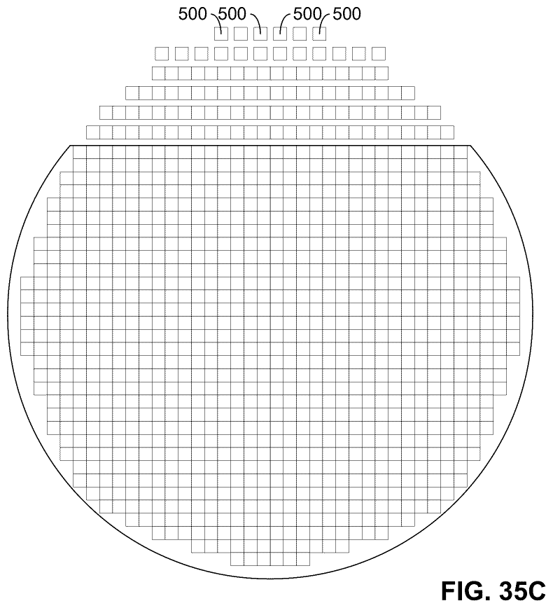

For example, FIGS. 35A to 35C show example stages of fabrication where multiple units are processed while in an array format and then singulated to provide multiple packaged units 500. More particularly, FIG. 35A shows a stage where a carrier 300 such as a wafer-shaped metal carrier is provided. Such a carrier can include an array of unit spaces 201, where each unit can be similar to the unit 201 described herein in reference to FIG. 5A, 9A, 32A or 34A.

FIG. 35B shows a stage where a die (110 in the example of FIG. 5B or FIG. 32B) has been placed on each unit 201, a mold layer has been formed to cover the array of units, and the carrier 300 has been removed, so as to form an assembly 302 of units 212, with each unit being similar to the unit 212 of FIG. 5D or FIG. 32D. It is noted that for the examples of FIGS. 9 and 34 where a thin packaging substrate layer is provided first on a carrier, the assembly 302 of FIG. 15B (after the removal of the carrier 300) can include an array of units with each unit being similar to the unit 216 of FIG. 9E or 34E.

FIG. 35C shows a stage where remaining process steps have been performed similar to the steps of respective processes, and the resulting array of formed modules are being singulated to provide multiple packaged modules 500.

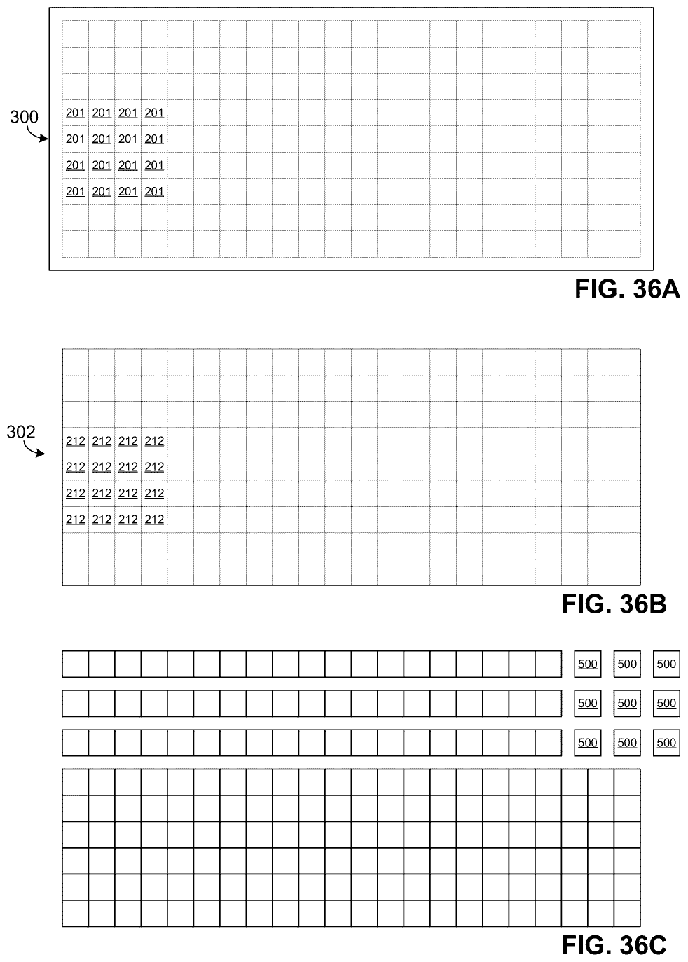

In the examples of FIGS. 35A to 35C, the carrier 300 is depicted as having a circular shape such as a wafer shape. However, it will be understood that such a carrier can have other shapes. For example, FIGS. 36A to 36C show that in some embodiments, a rectangular shaped carrier can be utilized to fabricate an array of modules having one or more features as described herein.

More particularly, FIG. 36A shows a stage where a carrier 300 such as a rectangular-shaped metal carrier is provided. Such a carrier can include an array of unit spaces 201, where each unit can be similar to the unit 201 described herein in reference to FIG. 35A.

FIG. 36B shows a stage where a die has been placed on each unit 201, a mold layer has been formed to cover the array of units, and the carrier 300 has been removed, so as to form an assembly 302 of units 212, with each unit being similar to the unit 212 of FIG. 35B.

FIG. 36C shows a stage where remaining process steps have been performed similar to the steps of respective processes, and the resulting array of formed modules are being singulated to provide multiple packaged modules 500.

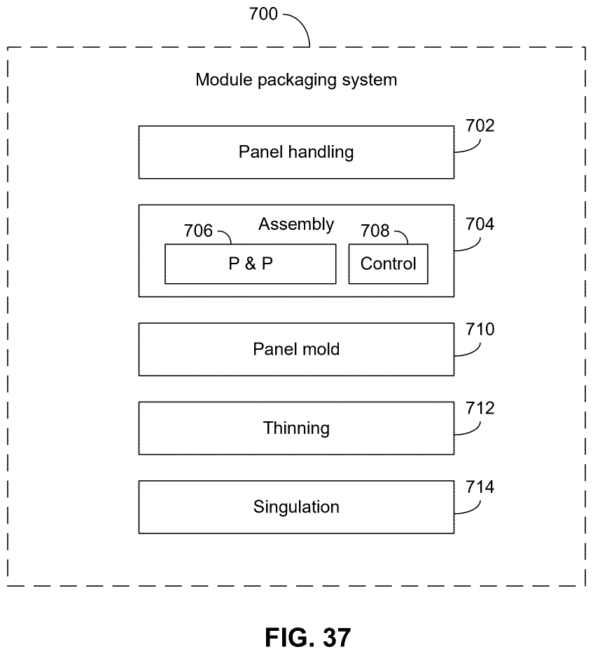

FIG. 37 shows that in some embodiments, one or more features of the present disclosure can be implemented in a module packaging system 700. Such a system can include a number of systems, subsystems, apparatus, etc. configured to provide respective functionalities. For example, a panel handling component 702 can be provided to allow handling of carriers, substrate panels and/or panel assemblies having mold layer(s) thereon.

In another example, an assembly component 704 can be provided to, for example, mounting of devices on at least one side (e.g., non-mounting side) of substrate panels, and formation of conductive features on at least one side (e.g., mounting side) side of substrate panels. In some embodiments, such an assembly functionality can be supported by, for example, a pick-and-place apparatus 706 in operation with a controller 708.

In yet another example, a panel mold component 710 can be provided to form some or all of panel mold layers as described herein. In some embodiments, such panel mold layer forming component can be configured to form a mold layer on at least one side of substrate panels.

In yet another example, a thinning component 712 can be provided to allow thinning of panel mold layers as described herein. In some embodiments, such thinning component can include a grinding functionality to remove material from a panel mold layer. In some embodiments, the grinding functionality can also include removal of material from back sides of die that are at least partially encapsulated by the panel mold layer.

In yet another example, a singulation component 714 can be provided to perform singulation operations on completed panel assemblies.

In some embodiments, some or all of the functional components of the module packaging system 700 of FIG. 37 can be performed under the control of, and/or facilitated by, a computer configured to execute one or more algorithms.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged module comprising:
a packaging substrate having first and second side with a plurality of layers therebetween in a printed circuit board configuration, and having a thickness that is less than 200 μm;
a first-side portion implemented on the first side of the packaging substrate and including a first component mounted on the first side of the packaging substrate, the first-side portion further including a first mold structure implemented to at least partially encapsulate the first component; and
a second-side portion implemented on the second side of the packaging substrate and including a second component mounted on the second side of the packaging substrate, and a plurality of conductive mounting structures, the second-side portion further including a second mold structure implemented to at least partially encapsulate the second component, the second mold structure further encapsulating the conductive mounting features while providing respective exposed mounting surfaces of the conductive mounting features.

2. The packaged module of claim 1 wherein the thickness of the packaging substrate is less than 150 μm, 100 μm, 90 μm, 80 μm, 70 μm, 60 μm, or 50 μm.

3. The packaged module of claim 1 wherein the packaging substrate includes a first outermost layer that defines the first side and a second outermost layer that defines the second side.

4. The packaged module of claim 3 wherein the first component is mounted directly on the first side, and the second component is mounted directly on the second side.

5. The packaged module of claim 1 wherein the first component is implemented as a die, and the second component is implemented as a die.

6. The packaged module of claim 5 wherein each of the first and second die is configured to provide a radio-frequency functionality.

7. The packaged module of claim 6 wherein the radio-frequency functionality of each of the first and second die includes a filtering functionality.

8. The packaged module of claim 7 wherein each of the first and second die is configured as an acoustic filter device.

9. The packaged module of claim 8 wherein the first acoustic filter device is a multilayer piezoelectric substrate (MPS) filter or a bulk acoustic wave (BAW) filter, and the second acoustic filter device is an MPS filter or a BAW filter.

10. The packaged module of claim 1 wherein the conductive mounting structures of the second-side portion are implemented as ball-shaped structures or as metal posts.

11. The packaged module of claim 1 wherein first mold structure is implemented to fully encapsulate non-mounting surface and side walls of the first component.

12. The packaged module of claim 1 wherein the first mold structure is implemented to expose a non-mounting surface of the first component.

13. The packaged module of claim 12 wherein the exposed non-mounting surface of the first component results from a thinning operation that removes a portion of the first component.

14. The packaged module of claim 13 wherein the exposed non-mounting surface of the first component includes a ground surface that provides a desired thickness of the first-side portion.

15. The packaged module of claim 1 wherein the second mold structure is implemented to fully encapsulate non-mounting surface and side walls of the second component.

16. The packaged module of claim 1 wherein the second mold structure is implemented to expose a non-mounting surface of the second component.

17. The packaged module of claim 16 wherein the exposed non-mounting surface of the second component results from a thinning operation that removes a portion of the second component.

18. The packaged module of claim 17 wherein the exposed non-mounting surface of the second component includes a ground surface that provides a desired thickness of the second-side portion.

19-27. (canceled)

28. A method for manufacturing a packaged module, the method comprising:
providing a carrier;
forming a first-side portion of a dual-sided module on the carrier;
removing the carrier from the first-side portion to provide a surface;
providing or forming a packaging substrate on the first-side portion such that the packaging substrate has a thickness less than 200 μm, and such that a first side of the packaging substrate engages the surface of the first-side portion and a second side of the packaging substrate is opposite from the first side; and
forming a second-side portion of the dual-sided module on the second side of the packaging substrate.

29-77. (canceled)

78. A packaged module comprising:
a packaging substrate having first and second sides with a plurality of layers therebetween in a printed circuit board configuration, and having a thickness that is less than 200 μm;
a filter die implemented on the first side of the packaging substrate, and a plurality of pins implemented on the second side of the packaging substrate, such that the packaging substrate include a fan out circuit between the filter die and the pins; and
a passive element implemented as part of the packaging substrate and configured to support operation of the filter die.

79-182. (canceled)
